(19) United States
(12) Patent Application Publication
(10) Pub. No.: US 2021/0159672 A1
(43) Pub. Date: May 27, 2021

(54) SURFACE EMITTING LASER DEVICE AND LIGHT EMITTING DEVICE INCLUDING SAME

(71) Applicant: LG INNOTEK CO., LTD., Seoul (KR)

(72) Inventors: Jeong Sik LEE, Seoul (KR); Sang Heon HAN, Seoul (KR); Keun Uk PARK, Seoul (KR); Yeo Jae YOON, Seoul (KR)

(73) Assignee: LG INNOTEK CO., LTD., Seoul (KR)

(21) Appl. No.: 17/256,546

(22) PCT Filed: Jun. 28, 2019
(86) PCT No.: PCT/KR2019/007880

§ 371 Date: Dec. 28, 2020

(30) Foreign Application Priority Data
Jun. 29, 2018 (KR) 10-2018-0075868
Jul. 13, 2018 (KR) 10-2018-0081613
Jul. 30, 2018 (KR) 10-2018-0088313

(51) Int. Cl. H01S 5/183

(52) U.S. Cl. CPC H01S 5/18377; H01S 5/18394

(57) ABSTRACT

An embodiment relates to a surface-emitting laser device and a light-emitting device including same. A surface-emitting laser device according to the embodiment can include: a first reflective layer; an active area disposed on the first reflective layer; an aperture area disposed on the active area; and a second reflective layer disposed on the aperture area. The second reflective layer can include: a first AlGaAs-based layer comprising Alₓ₁Ga₍₁₋ₓ₁₎As (wherein 0<X1<0.2); a second AlGaAs-based layer disposed on the first AlGaAs-based layer and comprising Alₓ₂Ga₍₁₋ₓ₂₎As (wherein 0.8<X2<1.0); and an AlGaAs-based transition area disposed between the first AlGaAs-based layer and the second AlGaAs-based layer. The AlGaAs-based transition area can include: a third AlGaAs-based layer comprising Alₓ₃Ga₍₁₋ₓ₃₎As (wherein 0<X3<0.2); and a fourth AlGaAs-based layer comprising Alₓ₄Ga₍₁₋ₓ₄₎As (wherein 0.8<X4<1.0).

### TECHNICAL FIELD

The embodiment relates to a semiconductor device, and more particularly, to a surface emitting laser device and a light emitting device including the same.

### BACKGROUND ART

A semiconductor device including a compound such as GaN or AlGaN has many advantages, such as having a wide and easily adjustable band gap energy, and thus can be used in various ways as a light emitting device, a light receiving device, and various diodes.

In particular, light emitting devices such as light emitting diodes and laser diodes using a group III-V or II-VI compound semiconductor material of semiconductors can be implemented various colors such as blue, red, green, and ultraviolet light. In addition, it is possible to implement highly efficient white light rays by using fluorescent materials or by combining colors. In addition, it has advantages of low power consumption, semi-permanent life, fast response speed, safety and environmental friendliness compared to conventional light sources such as fluorescent lamps and incandescent lamps.

In addition, when light-receiving devices such as photodetectors and solar cells are also manufactured using compound semiconductor materials of Groups III-V or II-VI of semiconductors, the development of device materials generates photocurrent by absorbing light in various wavelength ranges. By doing so, light in various wavelength ranges from gamma rays to radio wavelength ranges can be used. In addition, it has the advantages of fast response speed, safety, environmental friendliness, and easy control of device materials, so it can be easily used for power control or ultra-high frequency circuits or communication modules.

Accordingly, a light-emitting diode backlight is replacing a cold cathode fluorescent lamp (CCFL) constituting a transmission module of an optical communication means and a backlight of a liquid crystal display (LCD) display device. Applications are expanding to white light-emitting diode lighting devices that can replace fluorescent or incandescent bulbs, automobile headlights and traffic lights, and sensors that detect gas or fire.

In addition, applications can be extended to high-frequency application circuits, other power control devices, and communication modules. For example, in the conventional semiconductor light source device technology, there is a vertical-cavity surface emitting laser (VCSEL), which is used for optical communication, optical parallel processing, and optical connection. On the other hand, in the case of a laser diode used in such a communication module, it is designed to operate at a low current.

Meanwhile, response speed was important in the existing structure for data optical communication, but as it is recently applied to a high power PKG for a sensor, optical output and voltage efficiency become important characteristics.

For example, a 3D sensing camera is a camera capable of capturing depth information of an object, and has recently been in the spotlight in conjunction with augmented reality. On the other hand, for sensing the depth of the camera module, a separate sensor is mounted, and it is divided into two types: Structured Light (SL) method and Time of Flight (ToF) method.

In the structured light (SL) method, a laser of a specific pattern is radiated onto a subject, and the depth is calculated by analyzing the degree of deformation of the pattern according to the shape of the subject surface, and then combining it with a picture taken by an image sensor to obtain a 3D photographing result.

In contrast, the ToF method is a method in which a 3D photographing result is obtained by calculating the depth by measuring the time the laser is reflected off the subject and returning, and then combining it with the picture taken by the image sensor.

Accordingly, the SL method has an advantage in mass production in that the laser must be positioned very accurately, while the ToF technology relies on an improved image sensor, and it is possible to adopt either method or both methods in one mobile phone.

For example, a 3D camera called True Depth can be implemented in the front of a mobile phone in the SL method, and the ToF method can be applied in the rear.

Meanwhile, when a VCSEL is applied to a structured light sensor, a time of flight (ToF) sensor, or a laser diode autofocus (LDAF), it operates at a high current. Accordingly, problems such as a decrease in luminous intensity output or an increase in threshold current occur.

Accordingly, in VCSEL, unlike LEDs, the current density is very high, and ohmic design from the view of high reliability is required. For example, the current density is about 7-50 A/cm² in LED, but the current density is about 7000 A/cm² in VCSEL.

Accordingly, current crowding occurs in which the carrier density at the aperture edge rapidly increases as a low current to a high current is applied in the VCSEL of the related art, and current crowding occurs at the aperture edge such that there is a problem that the current injection efficiency is lowered.

In particular, DBR, which is a reflective layer in the related art, increases the reflectance by alternately arranging AlGaAs-based materials in different compositions of Al. However, an electric field is generated by energy band bending at the interface between these adjacent DBR layers, and this electric field becomes a carrier barrier, resulting in a problem of lowering the light output.

On the other hand, according to the internal technology, there is an attempt to lower the electrical resistance at the interface between the DBR layers, but there is a technical contradiction in that this attempt causes a problem of lowering the optical efficiency due to the increase in thermal resistance in the DBR layer.

In addition, in the related art, in order to prevent the occurrence of resistance in such a DBR, attempts have been made to increase the voltage efficiency by lowering the resistance by increasing the doping concentration, but when the doping concentration is increased, internal light absorption is generated by the dopant and the light output decreases.

On the other hand, when VCSEL is applied to a structured light sensor, ToF (Time of Flight) sensor, or LDAF (Laser Diode Autofocus), it operates at a high current, so the luminous intensity output decreases or the threshold current increases.

This is a situation in which VCSELs have very high current density unlike LEDs, and require an ohmic design from a high reliability perspective. For example, the current density is about 7-50 A/cm² in LED, but the current density is about 7000 A/cm² in VCSEL.

Accordingly, in the related art, current crowding occurs in which the carrier density at the aperture edge rapidly increases as a low current is applied to a high current, and current is injected due to the current density at the aperture edge such that there is a problem of lowering efficiency.

In particular, DBR, which is a reflective layer in the related art, increases reflectance by alternately arranging AlxGaAs-based materials with different Al compositions. However, an electric field is generated by energy band bending at the interface between these adjacent DBR layers, and this electric field becomes a carrier barrier, resulting in a problem of lowering the light output.

In addition, in the related art, in order to prevent the occurrence of resistance in such a DBR, attempts have been made to increase the voltage efficiency by lowering the resistance by increasing the doping concentration, but when the doping concentration is increased, internal light absorption is generated by the dopant and the light output decreases.

In addition, the conventional surface emitting laser device has the following technical problems.

First, in the VCSEL structure, reflectance is increased through a large number of reflective layers, for example, distributed Bragg reflectors (DBRs). For example, DBR increases the reflectance by alternately arranging AlxGaAs-based materials at different concentrations of Al. However, in order to solve the problem that series resistance occurs in the DBR, there is an attempt to improve the voltage efficiency by lowering the resistance by increasing the doping concentration of the DBR. However, when the doping concentration is increased, internal light absorption is generated by the dopant, resulting in a technical contradiction in which the light output decreases.

In addition, as DBR alternately arranges AlxGaAs-based materials at different concentrations of Al, the electric field is generated by energy band bending generated at the interface between adjacent layers in the DBR. The electric field is generated, and this electric field acts as a carrier barrier, resulting in a problem of lowering the light output.

Next, when developing a high-power package employing a VCSEL device, light output and voltage efficiency are important characteristics, and there is a limit to simultaneously improving the light output and voltage efficiency. For example, a VCSEL device includes an active region including an active layer and a cavity, and the active region has a technical problem in that a driving voltage increases due to a high internal resistance, thereby reducing voltage efficiency.

Next, in order to improve light output in the related art, optical confinement is required around the active layer, but there is no suitable solution for this in the related art.

Next, when current is applied to the surface emitting laser device, a current crowding phenomenon occurs in which the current is concentrated along the aperture edge. The film quality of the aperture, which is the laser emission area, may be damaged by the current concentration phenomenon. In addition, an optical problem occurs in that the temperature of the aperture is increased due to the current density phenomenon, and the divergence angle of beams passing through the aperture is increased. The effect of affecting the divergence angle of the beam passing through the aperture due to the current density phenomenon is called a thermal lens effect.

### DISCLOSURE

### Technical Problem

The embodiment is to provide a surface emitting laser device capable of improving electrical characteristics and a light emitting device including the same.

In addition, the embodiment is to provide a surface emitting laser device and a light emitting device including the same, which can improve light efficiency by not generating thermal resistance while improving electrical characteristics.

In addition, the embodiment is to provide a surface emitting laser device capable of improving light output while improving voltage efficiency and a light emitting device including the same.

In addition, the embodiment is to provide a surface emitting laser device capable of improving light output.

In addition, the embodiment is to provide a surface emitting laser device capable of improving light concentration efficiency.

In addition, the embodiment is to provide a surface emitting laser device capable of preventing fluctuations in a divergence angle of a beam by mitigating current concentration.

### Technical Solution

The surface emitting laser device according to the embodiment includes a first reflective layer 220, an active region 230 disposed on the first reflective layer 220, and an aperture region 240 disposed on the active region 230 and a second reflective layer 250 disposed on the aperture region 240.

The second reflective layer 250 includes a first AlGaAs-based layer 251a containing Alₓ₁Ga₍₁₋ₓ₁₎As (however, 0<X1<0.2), and a second AlGaAs-based layer 251b on the first AlGaAs-based layer 251a including Alₓ₂Ga₍₁₋ₓ₂₎As (but 0.8<X2<1.0) and a AlGaAs-based transition region 251t disposed between the first AlGaAs-based layer 251a and the second AlGaAs-based layer 251b.

The AlGaAs-based transition region 251t includes a third AlGaAs-based layer 251c containing Alₓ₃Ga₍₁₋ₓ₃₎As (however, 0<X3<0.2) and a fourth AlGaAs-based layer 251d including Alₓ₄Ga₍₁₋ₓ₄₎As (however, 0.8<X4<1.0).

A plurality of layers may be alternately disposed in the third AlGaAs-based layer 251c and the fourth AlGaAs-based layer 251d.

The plurality of third AlGaAs-based layers 251c may be thinner in a direction from the first AlGaAs-based layer 251a to the second AlGaAs-based layer 251b.

The plurality of fourth AlGaAs-based layers 251d may be thinner in a direction from the second AlGaAs-based layer 251b to the first AlGaAs-based layer 251a.

In addition, the Al concentration X3 of the third AlGaAs-based layer 251c may be higher than the Al concentration X1 of the first AlGaAs-based layer 251a.

In addition, the Al concentration X3 of the third AlGaAs-based layer 251c may be equal to or higher than the Al concentration X1 of the first AlGaAs-based layer 251a.

In addition, the Al concentration X1 of the first AlGaAs-based layer 251a and the Al concentration X3 of the third AlGaAs-based layer 251c may be 8% to 20%.

The Al concentration X4 of the fourth AlGaAs-based layer 251d may be lower than the Al concentration X2 of the second AlGaAs-based layer 251b.

In addition, the Al concentration X4 of the fourth AlGaAs-based layer 251d may be equal to or lower than the Al concentration X3 of the second AlGaAs-based layer 251b.

In addition, the Al concentration X4 of the fourth AlGaAs-based layer 251d and the Al concentration X2 of the second AlGaAs-based layer 251b may be 80% to 92%.

The Al concentration X3 in the third AlGaAs-based layer 251c may be 12% to 20% or less.

The Al concentration X4 in the fourth AlGaAs-based layer 251d may be 80% to 88% or less.

The thickness of the AlGaAs-based transition region 251t may be thinner than that of each of the first AlGaAs-based layer 251a and the second AlGaAs-based layer 25 lb.

The thickness of the plurality of third AlGaAs-based layers 251c may gradually decrease in a direction from the first AlGaAs-based layer 251a to the second AlGaAs-based layer 251b.

The thickness of the plurality of fourth AlGaAs-based layers 251d may gradually decrease from the second AlGaAs-based layer 251b toward the first AlGaAs-based layer 251a.

In addition, the surface emitting laser device according to the embodiment includes a first reflective layer 220, an active region 230 disposed on the first reflective layer 220, and an aperture region 240 disposed on the active region 230 and a second reflective layer 250 disposed on the aperture region 240.

The second reflective layer 250 includes a first AlGaAs-based layer 251a containing Alₓ₁Ga₍₁₋ₓ₁₎As (however, 0<X1<0.2), and a second AlGaAs-based layer including Alₓ₂Ga₍₁₋ₓ₂₎As (but 0.8<X2<1.0) on the first AlGaAs-based layer 251a and an AlGaAs-based transition region 251t disposed between the first AlGaAs-based layer 251a and the second AlGaAs-based layer 251b.

The AlGaAs-based transition region 251t includes a third AlGaAs-based layer 251c containing Alₓ₃Ga₍₁₋ₓ₃₎As (however, 0<X3<0.2) and a fourth AlGaAs-based layer 251d including Alₓ₄Ga₍₁₋ₓ₄₎As (however, 0.8<X4<1.0).

A plurality of layers may be alternately disposed in the third AlGaAs-based layer 251c and the fourth AlGaAs-based layer 251d.

The Al concentration X3 of the third AlGaAs-based layer 251c may be higher than the Al concentration X1 of the first AlGaAs-based layer 251a.

The Al concentration X4 of the fourth AlGaAs-based layer 251d may be lower than the Al concentration X2 of the second AlGaAs-based layer 251b.

The Al concentration X3 in the third AlGaAs-based layer 251c may be 12% to 20% or less.

The Al concentration X4 in the fourth AlGaAs-based layer 251d may be 80% to 88% or less.

The thickness of the AlGaAs-based transition region 251t may be thinner than that of each of the first AlGaAs-based layer 251a and the second AlGaAs-based layer 25 lb.

The plurality of third AlGaAs-based layers 251c may be thinner in a direction from the first AlGaAs-based layer 251a to the second AlGaAs-based layer 251b.

The thickness of the plurality of third AlGaAs-based layers 251c may gradually decrease in a direction from the first AlGaAs-based layer 251a to the second AlGaAs-based layer 251b.

The plurality of fourth AlGaAs-based layers 251d may be thinner in a direction from the second AlGaAs-based layer 251b to the first AlGaAs-based layer 251a.

The thickness of the plurality of fourth AlGaAs-based layers 251d may gradually decrease from the second AlGaAs-based layer 251b toward the first AlGaAs-based layer 251a.

The light emitting device of the embodiment may include the surface emitting laser device.

In addition, the surface emitting laser device according to the embodiment includes a first reflective layer, an active region including an active layer on the first reflective layer, and an aperture region disposed on the active region, and including an aperture and an insulating region and a second reflective layer on the aperture region.

The second reflective layer may include a second-first reflective layer, a second-second reflective layer, and a second-third reflective layer disposed between the second-first reflective layer and the second-second reflective layer.

The band gap energy level of the second-third reflective layer may be lower than the band gap energy level of the second-first reflective layer and higher than the band gap energy level of the second-second reflective layer.

The second reflective layer 250 may include a first superlattice tunneling layer 250s1 between the second-first reflective layer 251b and the second-third reflective layer 251c.

In addition, the surface emitting laser device according to the embodiment includes a first reflective layer, an active region including an active layer on the first reflective layer, and an aperture region disposed on the active region, and including an aperture and an insulating region and a second reflective layer on the aperture region.

The second reflective layer may include a second-first reflective layer, a second-second reflective layer, and a second-third reflective layer disposed between the second-first reflective layer and the second-second reflective layer.

The second reflective layer 250 includes a graded reflective layer 251g between the second-second reflective layer 251a and the second-third reflective layer 251c or between the second-first reflective layer 251b and the second-third reflective layer 251c, and a band gap energy level of the graded reflective layer 251g may include a rounding region.

Or the surface emitting laser device according to the embodiment includes a substrate; a first reflective layer disposed on the substrate; an active layer disposed on the first reflective layer; an oxide layer disposed on the active layer and including an aperture and an insulating region; and a second reflective layer disposed on the oxide layer and including a current diffusion layer. The doping concentration of the current diffusion layer may be 5E17/cm³ or less.

In addition, the surface emitting laser device according to the embodiment includes a substrate; a first reflective layer disposed on the substrate; an active layer disposed on the first reflective layer; an oxide layer disposed on the active layer and including an aperture and an insulating region; and a second reflective layer disposed on the oxide layer and including a current diffusion layer. The current diffusion layer is disposed between the second reflective layer and the first reflective layer, and may diffuse a current flowing vertically in a horizontal direction.

The light emitting device of the embodiment may include the surface emitting laser device.

### Advantageous Effects

The embodiment may provide a surface emitting laser device capable of improving electrical characteristics and a light emitting device including the same.

In addition, the embodiment can provide a surface emitting laser device and a light emitting device including the same, which can improve light efficiency by not generating thermal resistance while improving electrical characteristics.

For example, according to an embodiment, the Al concentration (X3) of the third AlGaAs-based layer 251c is higher than the Al concentration (X1) of the first AlGaAs-based layer 251a but lower than 20% such that thermal resistance can be prevented from being caused, and the Al concentration (X4) of the fourth AlGaAs-based layer 251d is lower than the Al concentration (X2) of the second AlGaAs-based layer 251b, but more than 80% such that it can be controlled to prevent the occurrence of thermal resistance.

For example, in the embodiment, the AlGaAs-based transition region 251t has a third AlGaAs-based layer 251c of Alₓ₃Ga₍₁₋ₓ₃₎As (however, X1<X3<0.2) having low thermal resistance and thermal resistance. A fourth AlGaAs-based layer 251d of low Alₓ₄Ga₍₁₋ₓ₄₎As (however, 0.8<X4<X2) is included, and the AlGaAs-based transition region 251t is disposed between the first AlGaAs-based layer 251a and the second AlGaAs-based layer 251b, so that thermal resistance is not generated, thereby improving light efficiency and improving electrical characteristics.

In addition, according to an embodiment, the first thickness T1 of the plurality of third AlGaAs-based layers 251c may gradually decrease from the first AlGaAs-based layer 251a to the second AlGaAs-based layer 251b. In addition, the plurality of fourth AlGaAs-based layers 251d may be thinner in a direction from the second AlGaAs-based layer 251b to the first AlGaAs-based layer 251a. Through this, according to the embodiment, it is possible to maximize the tunneling effect to obtain a complex technical effect of the effect of reducing the electrical resistance and the effect of reducing thermal resistance.

In addition, the embodiment can provide a surface emitting laser device capable of improving light output while improving voltage efficiency and a light emitting device including the same.

The embodiment may provide a surface emitting laser device capable of improving electrical characteristics and a light emitting device including the same.

For example, according to the embodiment, since the first superlattice tunneling layer 250s1 is disposed between the second-first reflective layer 251b and the second-third reflective layer 251c, or a second superlattice tunneling layer 250s2 is disposed between the second-first reflective layer 251b and the second-second reflective layers 251a, there is a special technical effect to facilitate carrier movement through the carrier's turning (CT) effect, thereby reducing resistance within the DBR and preventing an increase in driving voltage.

Also, for example, since the second reflective layer 250 of the embodiment can include a graded reflective layer (251g) between the second-second reflective layer 251a and the second-third reflective layer 251c or between the second-first reflective layer 251b and the second-third reflective layer 251c, a rounding area of bandgap energy is provided at the boundary between each reflective layer, thereby minimizing the band tail phenomenon, thereby facilitating carrier movement (CM) within the reflective layer such that there is a technical effect of reducing resistance and preventing an increase in driving voltage.

In addition, the embodiment can provide a surface emitting laser device capable of improving light output while improving voltage efficiency and a light emitting device including the same.

For example, according to the embodiment, the concentration of the second conductivity-type dopant in the second-fourth reflective layer, which is the node position where the refractive index is relatively lower in optical reflectivity, is controlled to be high to improve the electrical characteristics, thereby improving the voltage efficiency. So, it is possible to provide a surface emitting laser device capable of improving output and a light emitting device including the same.

In addition, according to at least one of the embodiments, the first group of the second reflective layer on the emission layer includes a second conductive type dopant having a relatively low energy band gap and a low doping concentration in the second reflective layer, or by including a layer that does not contain a second conductivity type dopant, resistance is increased in the layer so that holes in the second reflective layer may diffuse in the plane direction of the layer. Accordingly, since the current density phenomenon in which the current in the second reflective layer is concentrated along the aperture edge is alleviated or eliminated, the divergence angle of the beam of the light emitting layer is not changed, so that reliability and quality of the product may be improved.

According to at least one of the embodiments, a layer including a second conductivity type dopant having a relatively low energy band gap or a low doping concentration, or a first conductivity type dopant or not containing a second conductivity type dopant may be included in not only the first group second reflective layer but also the second group second reflective layer in the second reflective layer. The corresponding layer of the second reflective layer of the first group and the corresponding layer of the second group second reflective layer increase in resistance, so that the hole of the second reflective layer becomes the corresponding layer of the second reflective layer of the first group and the corresponding layer of the second group second reflective layer. It can diffuse in each plane direction. Accordingly, since the current concentration phenomenon in which the current in the second reflective layer is concentrated along the aperture edge is more reliably alleviated or eliminated, the divergence angle of the beam of the light emitting layer is not changed, so that reliability and quality of the product may be improved.

According to at least one of the embodiments, a second-third reflective layer or second-fourth reflective layer having an intermediate aluminum concentration of the third and fourth aluminum concentrations respectively may be disposed between second-first reflective layer and second-second-second reflective layer of the second reflective layer adjacent to light emitting layer. As a result, generation of an electric field due to bending of an energy band at the interface between each layer of the second reflective layer is minimized, thereby lowering the carrier barrier, thereby improving light output.

Further scope of applicability of the embodiments will become apparent from the detailed description below. However, various changes and modifications within the spirit and scope of the embodiments may be clearly understood by those skilled in the art, and thus specific embodiments such as detailed description and preferred embodiments should be understood as being given by way of example only.

### DESCRIPTION OF DRAWINGS

FIG. 1 is a plan view of a surface emitting laser device according to an embodiment.

FIG. 2 is an enlarged view of a portion C1 of the surface emitting laser device according to the embodiment shown in FIG. 1.

FIG. 3 is a first cross-sectional view taken along line A1-A2 of the surface emitting laser device according to the embodiment shown in FIG. 2.

FIG. 4 is a cross-sectional view of a portion B1 of an epi region of the surface emitting laser device according to the embodiment shown in FIG. 3.

FIG. 5A is a first energy band diagram of a first region 250S of a second reflective layer of the surface emitting laser device according to the embodiment illustrated in FIG. 4.

FIG. 5B is data of thermal resistance according to Al composition in a second reflective layer of a surface emitting laser device.

FIG. 6A is a partially enlarged view of a second reflective layer of a surface emitting laser device according to an embodiment.

FIG. 6B is a surface emitting laser device according to an embodiment and optical power data according to an applied current of a comparative example.

FIG. 7 is distribution data of a refractive index and light energy in a surface emitting laser device according to an embodiment.

FIG. 8 is a second partial enlarged view of a second reflective layer of a surface emitting laser device according to an embodiment.

FIGS. 9 to 16B are manufacturing process diagrams of a surface emitting laser device according to an embodiment.

FIG. 17 is another cross-sectional view of a surface emitting laser device according to an embodiment.

FIG. 18A is another first energy band diagram for a first area of a second reflective layer of the surface emitting laser device according to the embodiment shown in FIG. 4.

FIG. 18B is a first application example of a first area of a second reflective layer of a surface emitting laser device according to the embodiment shown in FIG. 18A.

FIG. 18C is a second application example of a first area of a second reflective layer of the surface emitting laser device according to the embodiment shown in FIG. 18A.

FIG. 19 is a second energy band diagram for a first region of a second reflective layer of the surface emitting laser device according to the embodiment illustrated in FIG. 4.

FIG. 20 is data on the Al concentration distribution in the second reflective layer of the surface emitting laser device according to the second additional embodiment.

FIGS. 21A and 21B show the degree of current density according to the related art and the second additional embodiment.

FIG. 22 is data on the Al concentration distribution in the second reflective layer of the surface emitting laser device according to the third additional embodiment.

FIG. 23 shows the degree of current density according to the third additional embodiment.

FIG. 24 is a perspective view of a mobile terminal to which a surface emitting laser device is applied according to an embodiment.

### MODE FOR INVENTION

Hereinafter, preferred embodiments of the present invention will be described in detail with reference to the accompanying drawings. However, the technical idea of the present invention is not limited to some embodiments to be described, but may be implemented in various different forms, and within the scope of the technical idea of the present invention, one or more of the constituent elements may be selectively selected between the embodiments. It can be combined with and substituted for use.

In addition, terms (including technical and scientific terms) used in the embodiments of the present invention are generally understood by those of ordinary skill in the art, unless explicitly defined and described. It can be interpreted as a meaning, and terms generally used, such as terms defined in a dictionary, may be interpreted in consideration of the meaning in the context of the related technology.

In addition, terms used in the embodiments of the present invention are for describing the embodiments and are not intended to limit the present invention.

In this specification, the singular form may also include the plural form unless specifically stated in the phrase, and when described as “and at least one (or more than one) of B and C”, it may be combined with A, B, C. It can contain one or more of all possible combinations.

In addition, in describing the constituent elements of the embodiments of the present invention, terms such as first, second, a, B, (a), and (b) may be used. These terms are only for distinguishing the component from other components, and are not limited to the nature, order, or order of the component by the term.

And, when a component is described as being ‘connected’, ‘coupled’ or ‘contacted’ to another component, the component is not only directly connected, coupled or connected to the other component, but also the component and the case of being ‘connected’, ‘coupled’, or ‘contacted’ due to another element between the other elements may also be included.

In addition, when it is described as being formed or disposed on the “top or bottom” of each component, the top or bottom is one as well as when the two components are in direct contact with each other. It includes a case in which the above other component is formed or disposed between the two components.

In addition, when expressed as “upper or lower”, the meaning of not only an upward direction but also a downward direction based on one component may be included.

### Embodiment

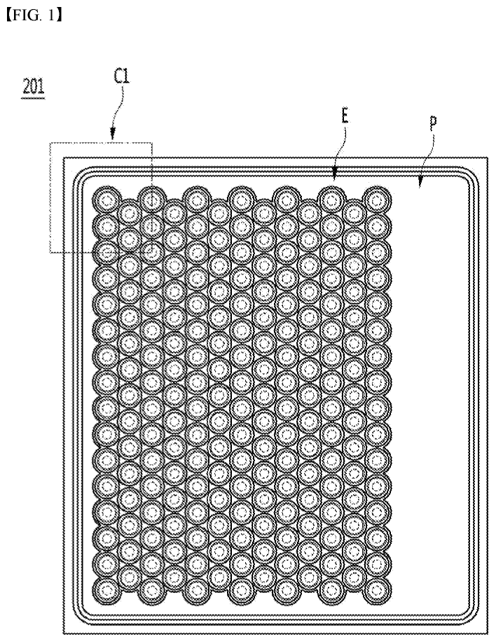

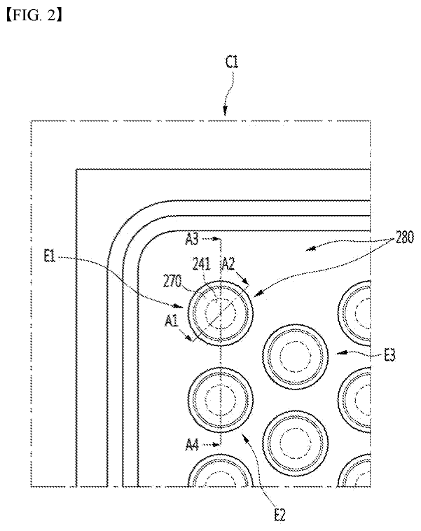

FIG. 1 is a plan view of a surface emitting laser device 201 according to an embodiment, and FIG. 2 is an enlarged view of a portion C1 of the surface emitting laser device according to the embodiment shown in FIG. 1.

Referring to FIG. 1, a surface emitting laser device 201 according to an embodiment may include a light emitting part E and a pad part P, and the light emitting part E may include a plurality of light emitting emitters as shown in FIG. 2. Emitters E1, E2, and E3 may be included, and tens to hundreds of light emitting emitters may be included.

Referring to FIG. 2, in the embodiment, in the surface emitting laser device 201, a second electrode 280 are disposed in an area other than the aperture 241, which is an opening, and a passivation layer 270 is disposed on the surface corresponding to the aperture 241.

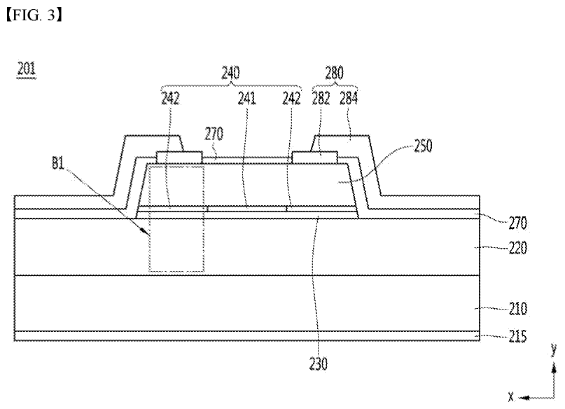

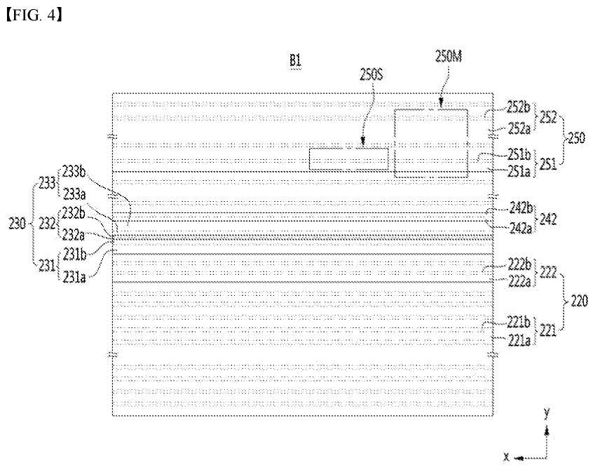

Next, FIG. 3 is a cross-sectional view along line A1-A2 of the surface emitting laser device according to the embodiment shown in FIG. 2, and FIG. 4 is an enlarged sectional view of (B1) of a part of an epi region of the surface emitting laser device according to the embodiment shown in FIG. 0.3.

Referring to FIG. 3, in the embodiment, the surface emitting laser device 201 includes a first electrode 215, a substrate 210, a first reflective layer 220, an active region 230, an aperture region 240, at least one of the reflective layer 250, the second electrode 280, and the passivation layer 270.

The aperture region 240 may include an aperture 241 that is opening and an insulating region 242. The insulating region 242 serves as a current blocking function and may be referred to as an oxide layer, and the aperture region 240 may be referred to as an oxidation region, but is not limited thereto.

The second electrode 280 may include a contact electrode 282 and a pad electrode 284.

Hereinafter, the technical features of the surface emitting laser device 201 according to the embodiment will be described with reference to FIGS. 3 and 4, and the technical effects will be described with reference to the drawings. In the drawings of the embodiment, the x-axis direction may be a direction parallel to the length direction of the substrate 210, and the y-axis may be a direction perpendicular to the x-axis.

<Substrate, First Electrode>

First, referring to FIG. 3, in the embodiment, the substrate 210 may be a conductive substrate or a non-conductive substrate. When a conductive substrate is used, a metal having excellent electrical conductivity can be used, and since it is able to sufficiently dissipate heat generated when the surface emitting laser device 201 is operated, a GaAs substrate or a metal substrate having high thermal conductivity can be used, or silicon (Si) substrate, etc. can be used. When using a non-conductive substrate, an AlN substrate, a sapphire (Al₂O₃) substrate, or a ceramic-based substrate may be used.

The substrate 210 shown in FIG. 3 may be a substrate doped with an n-type conductivity type, but embodiments are not limited thereto.

In an embodiment, the first electrode 215 may be disposed under the substrate 210, and the first electrode 215 may be disposed as a single layer or multiple layers of a conductive material. For example, the first electrode 215 may be a metal, and at least one of aluminum (Al), titanium (Ti), chromium (Cr), nickel (Ni), copper (Cu), and gold (Au). It is formed in a single-layer or multi-layer structure to improve electrical properties, thereby increasing light output. Since the first electrode 215 can function as an electrode for the first reflective layer 220 functioning as an n-type reflective layer, it may be referred to as an n-type electrode, but the first electrode 215 itself contains a conductive element and is not doped.

<First Reflective Layer, Second Reflective Layer>

Next, referring to FIG. 4, the first reflective layer 220 may be doped with a first conductivity type. The first conductivity-type dopant may include an n-type dopant such as Si, Ge, Sn, Se, and Te.

In addition, the first reflective layer 220 may include a gallium-based compound, for example, AlGaAs, but is not limited thereto. The first reflective layer 220 may be a Distributed Bragg Reflector (DBR). For example, the first reflective layer 220 may have a structure in which a first layer and a second layer made of materials having different refractive indices are alternately stacked at least once or more.

For example, as shown in FIG. 4, the first reflective layer 220 includes a first group first reflective layer 221 disposed on the substrate 210 and a second group first reflective layer 222 on the first group first reflective layer 221.

The first group first reflective layer 221 and the second group first reflective layer 222 may include a plurality of layers made of a semiconductor material having a composition formula of AlₓGa₍₁₋ₓ₎As(0<x<1). When Al in each layer increases, the refractive index of each layer decreases, and when Ga increases, the refractive index of each layer may increase.

In addition, the thickness of each layer may be λ, λ may be a wavelength of light generated from the active layer 232, and n may be a refractive index of each layer with respect to light of the above-described wavelength. Here, λ may be 650 to 980 nanometers (nm), and n may be the refractive index of each layer. The first reflective layer 220 having such a structure may have a reflectance of 99.999% for light in a wavelength region of about 940 nanometer.

The thickness of the layer in each of the first reflective layers 220 may be determined according to a respective refractive index and a wavelength λ of light emitted from the active layer 232.

In addition, as shown in FIG. 4, the first group first reflective layer 221 and the second group first reflective layer 222 may be formed of a single layer or a plurality of layers, respectively.

For example, the first group first reflective layer 221 may include about 30 to 40 pairs of the first group first-first layer 221a and the first group first-second layer 221b. The first group first-first layer 221a may be formed to be thicker than the first group first-second layer 221b. For example, the first group first-first layer 221a may be formed to be about 40 to 60 nm, and the first group first-second layer 221b may be formed to be about 20 to 30 nm.

In addition, the second group first reflective layer 222 may also include about 5 to 15 pairs of the second group first-first layer 222a and the second group first-second layer 222b. The second group first-first layer 222a may be formed to be thicker than the second group first-second layer 222b. For example, the second group first-first layer 222a may be formed to be about 40 to 60 nm, and the second group first-second layer 222b may be formed to be about 20 to 30 nm.

In addition, as shown in FIG. 4, the second reflective layer 250 may include a gallium-based compound, for example, AlGaAs, and the second reflective layer 250 may be doped with a second conductivity type dopant.

For example, the second conductivity-type dopant may be a p-type dopant such as Mg, Zn, Ca, Sr, Ba, or the like.

The second reflective layer 250 may also be a Distributed Bragg Reflector (DBR). For example, the second reflective layer 250 may have a structure in which a plurality of layers made of materials having different refractive indices are alternately stacked at least once or more.

Each layer of the second reflective layer 250 may include AlGaAs, and in detail, may be made of a semiconductor material having a composition formula of AlₓGa₍₁₋ₓ₎As(0<x<1). Here, when Al increases, the refractive index of each layer decreases, and when Ga increases, the refractive index of each layer may increase. In addition, the thickness of each layer of the second reflective layer 250 is λ/4n, λ may be a wavelength of light emitted from the active layer, and n may be a refractive index of each layer with respect to the light of the above-described wavelength.

The second reflective layer 250 having such a structure may have a reflectance of 99.9% for light in a wavelength region of about 940 nanometers.

The second reflective layer 250 may be formed by alternately stacking layers, and the number of pairs of layers in the first reflective layer 220 may be greater than the number of pairs of layers in the second reflective layer 250. In this case, as described above, the reflectance of the first reflective layer 220 is about 99.999%, which may be greater than the reflectance of 99.9% of the second reflective layer 250.

In an embodiment, the second reflective layer 250 may include a first group second reflective layer 251 disposed adjacent to the active region 230 and a second group second reflective layer 252 spaced apart from the active region 230 than the first group second reflective layer 251.

As shown in FIG. 4, the first group second reflective layer 251 and the second group second reflective layer 252 may also be formed of a single layer or a plurality of layers, respectively.

For example, the first group second reflective layer 251 may include about 1 to 5 pairs of the first group second-first layer 251a and the first group second-second layer 25 lb. The first group second-first layer 251a may be formed to be thicker than the first group second-second layer 251b. For example, the first group second-first layer 251a may be formed to be about 40 to 60 nm, and the first group second-second layer 251b may be formed to be about 20 to 30 nm.

In addition, the second group second reflective layer 252 may also include about 5 to 15 pairs of the second group second-first layer 252a and the second group second-second layer 252b. The second group second-first layer 252a may be formed to be thicker than the second group second-second layer 252b. For example, the second group second-first layer 252a may be formed to be about 40 to 60 nm, and the second group second-second layer 252b may be formed to be about 20 to 30 nm.

First, one of the technical problems of the embodiment is to provide a surface emitting laser device capable of improving electrical properties and a light emitting device including the same.

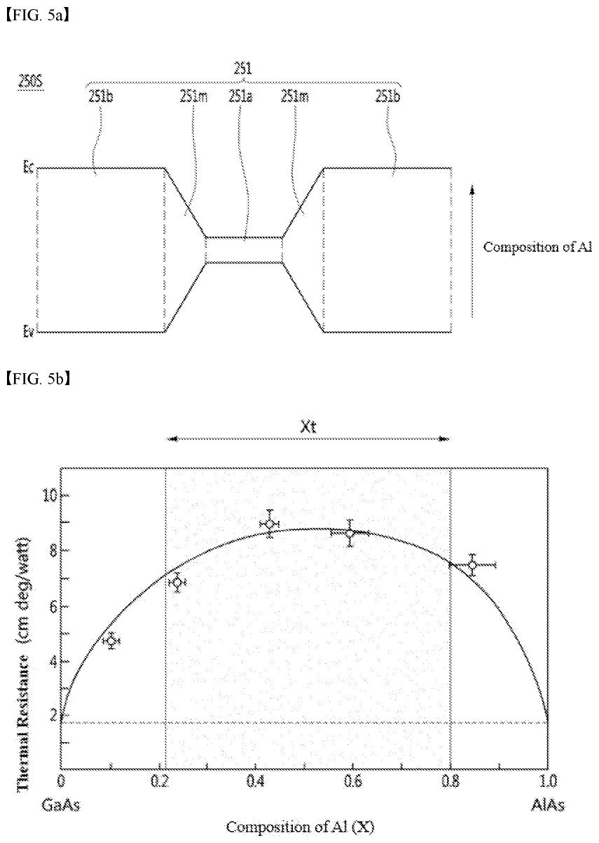

FIG. 5A is a first energy band diagram of a first region 250S of a second reflective layer of the surface emitting laser device according to the embodiment illustrated in FIG. 4, and is illustrated based on an Al composition.

The following description will be described centering on the second reflective layer 250, but the technical features of the embodiment may be applied to the first reflective layer 220 as well.

First, referring to FIG. 5A, the first group second reflective layer 251 of the embodiment may include a plurality of layers. For example, the first group second reflective layer 251 of the embodiment may include a first AlGaAs-based layer 251a and a second AlGaAs-based layer 251b, and a grading AlGaAs-based layer 251m therebetween.

According to the embodiment, by providing a grading AlGaAs-based layer 251m having an aluminum concentration in an intermediate region between the adjacent first AlGaAs-based layer 251a and the second AlGaAs-based layer 251b, there is a technical effect of improving light output by lowering a carrier barrier at interface between adjacent reflective layers by minimizing the generation of an electric field due to energy band bending.

For example, when the first group second reflective layer 251 includes AlₓGa₍₁₋ₓ₎As(0<x<1), the first group second reflective layer 251 is Alₓ₁Ga₍₁₋ₓ₁₎As (however, 0<X1<0.2) is disposed on the first AlGaAs-based layer 251a and the first AlGaAs-based layer 251a, and Alₓ₂Ga₍₁₋ₓ₂₎As (however, al y1 Ga (1-y1) disposed between the second AlGaAs-based layer 251b including 0.8<X2<1.0) and the first AlGaAs-based layer 251a and the second AlGaAs-based layer 251b) A graded AlGaAs-based layer 251m including As (however, X1<y1<X2) may be included.

For example, when the first group second reflective layer 251 includes AlₓGa₍₁₋ₓ₎As(0<x<1), the first group second reflective layer 251 includes a first AlGaAs-based layer 251a having a composition of Alₓ₁Ga₍₁₋ₓ₁₎As (however, 0<X1<0.2), a second AlGaAs-based layer 251b having a composition of Alₓ₂Ga₍₁₋ₓ₂₎As (however, 0.8<X2<1.0), and a grading AlGaAs-based layer (251m) having a composition of Al_{y1}Ga_{(1-y1)}As (however, X1<y1<X2) disposed between the second AlGaAs-based layer 251b and the first AlGaAs-based layer 251a.

Through this, according to an embodiment, since a grading AlGaAs-based layer 251m having an aluminum concentration in an intermediate region between the adjacent first AlGaAs-based layer 251a and the second AlGaAs-based layer 251b is provided, there is a technical effect of improving light output by minimizing the generation of an electric field due to energy band bending and lowering a carrier barrier at interface between adjacent reflective layers.

Accordingly, according to the embodiment, it is possible to provide a surface emitting laser device capable of improving light output by minimizing the influence of a carrier barrier due to generation of an electric field in a reflective layer, and a light emitting device including the same.

On the other hand, one of the technical problems of the embodiment is to provide a surface emitting laser device and a light emitting device including the same, which can improve light efficiency by not generating thermal resistance while improving electrical properties.

Hereinafter, a technical feature of an embodiment capable of solving this technical contradiction will be described.

First, FIG. 5B is data of thermal resistance according to the Al composition in the second reflective layer of the surface emitting laser device.

As described above, according to the internal technology, there is an attempt to lower the electrical resistance at the interface between the DBR layers, but there is a technical contradiction in that this attempt causes a problem of lowering the optical efficiency due to the increase in thermal resistance in the DBR layer.

Specifically, according to an embodiment, a grading AlGaAs-based layer 251m having an aluminum concentration graded with an Al composition in an intermediate region between the first AlGaAs-based layer 251a and the second AlGaAs-based layer 251b. Through this, the light output can be improved by reducing the carrier barrier by minimizing the generation of an electric field due to energy band bending at the interface between adjacent reflective layers, and there are technical effects in that high resistance characteristics due to continuous band offset at the DBR interface are alleviated.

However, as shown in FIG. 5B, the AlGaAs of the reflective layer has a higher thermal resistance due to alloy scattering in the Al composition (X) between 20% and 80% (Xt region), and in particular, as the Al composition approaches 50%, it shows a characteristic that the heat resistance increases rapidly.

In other words, according to internal technology, when a grading AlGaAs-based layer (251m) is inserted at the high/low refractive index interface to reduce the electrical resistance in the DBR layer, the Al composition is in the range of about 20 to 80% (Xt), the heat resistance increases due to alloy scattering. Accordingly, according to the application of the graded AlGaAs-based layer (251m) inserted to reduce electrical resistance, there is a technical contradiction in which optical efficiency is lowered due to the generation of thermal resistance.

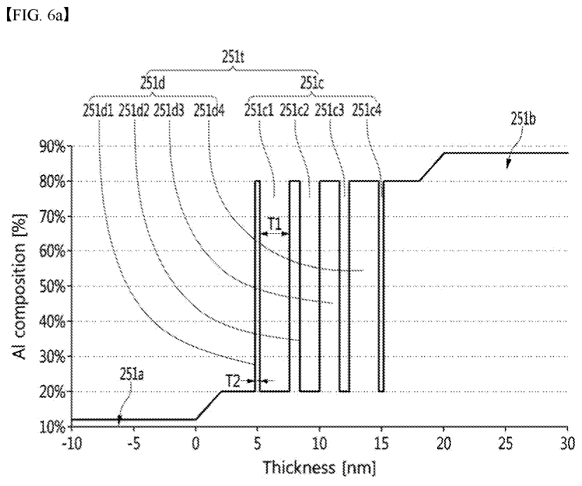

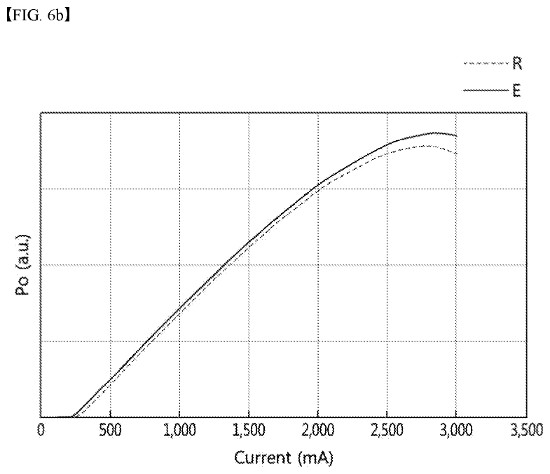

FIG. 6A is a partial enlarged view of a second reflective layer of a surface emitting laser device according to an embodiment, showing Al composition data according to thickness, and FIG. 6B is a surface emitting laser device according to an embodiment and optical power data according to an applied current of a comparative example.

In order to solve the technical contradiction described above, as shown in FIG. 6A, the second reflective layer 250 of the embodiment includes an AlGaAs-based transition region 251t disposed between the first AlGaAs-based layer 251a and the second AlGaAs-based layer 251b.

According to an embodiment, a surface light emitting laser device and a light emitting device including the same having a complex technical effect capable of improving optical efficiency by not generating thermal resistance while improving electrical characteristics by providing an AlGaAs-based transition region 251t with low or no thermal resistance.

Specifically, the second reflective layer 250 of the embodiment includes a first AlGaAs-based layer 251a containing Alₓ₁Ga₍₁₋ₓ₁₎As (however, 0<X1<0.2), and a second AlGaAs-based layer 251b containing Alₓ₂Ga₍₁₋ₓ₂₎As (however, 0.8<X2<1.0) disposed on the first AlGaAs-based layer 251a, and an AlGaAs-based transition region 251t disposed between the first AlGaAs-based layer 251a and the second AlGaAs-based layers 251b.

In this case, in the embodiment, the AlGaAs-based transition region 251t includes a third AlGaAs-based layer 251c containing Alₓ₃Ga₍₁₋ₓ₃₎As (however, 0<X3<0.2) and a fourth AlGaAs-based layer 251d containing Alₓ₄Ga₍₁₋ₓ₄₎As (however, 0.8<X4<1.0), and the third AlGaAs-based layer 251c and the fourth AlGaAs-based layer 251d are alternately arranged.

In an embodiment, the Al concentration X3 of the third AlGaAs-based layer 251c may be equal to or higher than the Al concentration X1 of the first AlGaAs-based layer 251a.

In addition, the Al concentration X1 of the first AlGaAs-based layer 251a and the Al concentration X3 of the third AlGaAs-based layer 251c may be 8% to 20%.

In addition, the Al concentration X4 of the fourth AlGaAs-based layer 251d may be equal to or lower than the Al concentration X2 of the second AlGaAs-based layer 251b.

In addition, the Al concentration X4 of the fourth AlGaAs-based layer 251d and the Al concentration X2 of the second AlGaAs-based layer 251b may be 80% to 92%.

According to an embodiment, the Al concentration X3 of the third AlGaAs-based layer 251c is higher than the Al concentration X1 of the first AlGaAs-based layer 251a but is controlled to 20% or less, to prevent thermal resistance being generated. The Al concentration (X4) of the fourth AlGaAs-based layer 251d is lower than the Al concentration (X2) of the second AlGaAs-based layer 251b, but is controlled to be 80% or more, to prevent thermal resistance being generated.

For example, in the embodiment, since the AlGaAs-based transition region 251t has the third AlGaAs-based layer 251c of Alₓ₃Ga₍₁₋ₓ₃₎As (however, X1<X3<0.2) having low thermal resistance and the fourth AlGaAs-based layer 251d of Alₓ₄Ga₍₁₋ₓ₄₎As (however, 0.8<X4<X2) having low thermal resistance, and the AlGaAs-based transition region 251t is disposed between the first AlGaAs-based layer 251a and the second AlGaAs-based layer 251b, thermal resistance is not generated, thereby improving light efficiency and improving electrical characteristics.

For example, in the high current region of 2,000 mA to 2,500 mA or more as shown in FIG. 6B, optical power is significantly lowered due to the generation of thermal resistance as in Comparative Example (R). According to exemplary Example (E), the AlGaAs series transition region 251t is disposed between the first AlGaAs-based layer 251a and the second AlGaAs-based layer 251b so that thermal resistance is not generated, thereby improving light efficiency and improving electrical characteristics.

Referring back to FIG. 6A, according to the embodiment, the concentration X3 of Al in the third AlGaAs-based layer 251c may be controlled to 8% to 20% or less, preferably 12% to 20% or less. Through this, the Al concentration X3 of the third AlGaAs-based layer 251c is controlled to be 20% or less so that thermal resistance can be prevented, and the Al concentration of the third AlGaAs-based layer 251c X3 is controlled to be 8% or more, preferably 12% or more, and is controlled to be equal to or higher than the Al concentration X1 of the first AlGaAs-based layer 251a, so that there is a technical effect of minimizing the difference with Al concentration of the fourth AlGaAs-based layer 251d formed thereafter to reduce thermal resistance while maintaining or improving crystal quality or electrical resistance characteristics.

In addition, the concentration X4 of Al in the fourth AlGaAs-based layer 251d may be controlled to 80% to 92% or less, preferably 80% to 88% or less. Through this, the Al concentration X4 of the fourth AlGaAs-based layer 251d can be controlled to be 80% or more to prevent thermal resistance from being induced, and the Al concentration of the fourth AlGaAs-based layer 251d is controlled to 92% or less, preferably 88% or less, and is controlled to be equal to or lower than the Al concentration X4 of the fourth AlGaAs-based layer 251d, such that there is a technical effect of minimizing the difference with the Al concentration (X3) of the third AlGaAs-based layer 251c to be formed thereafter to reduce thermal resistance while maintaining or improving crystal quality or electrical resistance characteristics.

Referring to FIG. 6A, the thickness of the AlGaAs-based transition region 251t in the second reflective layer 250 may be thinner than each of the first AlGaAs-based layer 251a and the second AlGaAs-based layer 251b. That is, the thickness of each of the first AlGaAs-based layer 251a and the second AlGaAs-based layer 251b may be thicker than the thickness of the AlGaAs-based transition region 251t.

For example, each of the first AlGaAs-based layer 251a and the second AlGaAs-based layer 251b may have a thickness in a range of 2 to 3 times greater than the thickness of the AlGaAs-based transition region 251t.

For example, the thickness of the AlGaAs-based transition region 251t may be about 15 nm to 28 nm, and the thickness of each of the first AlGaAs-based layer 251a and the second AlGaAs-based layer 251b is about 30 nm to 84 nm, but is not limited thereto.

According to the embodiment, the thickness of the AlGaAs-based transition region 251t is formed to be thinner than each of the first AlGaAs-based layer 251a and the second AlGaAs-based layer 251b such that there is a technical effect of minimizing the generation of resistance to improve light efficiency and to improve electrical characteristics.

In addition, in an embodiment, the plurality of third AlGaAs-based layers 251c may be thinner in a direction from the first AlGaAs-based layer 251a to the second AlGaAs-based layer 251b.

In addition, the first thickness T1 of the plurality of third AlGaAs-based layers 251c may gradually decrease from the first AlGaAs-based layer 251a to the second AlGaAs-based layer 251b.

For example, the plurality of third AlGaAs-based layers 251c include a third-first AlGaAs-based layer 251c1, a third-second AlGaAs-based layer 251c2, a third-third AlGaAs-based layer 251c3, and a third-fourth AlGaAs-based layer 251c4, and there is complex technical effect in that the plurality of third AlGaAs-based layers 251c is formed of 4 nm or less, for example, 4 nm, 3 nm, 2 nm and 1 nm, respectively, to maximize the tunneling effect, thereby reducing the electrical resistance and reducing thermal resistance.

In addition, the plurality of fourth AlGaAs-based layers 251d may be thinner in a direction from the second AlGaAs-based layer 251b to the first AlGaAs-based layer 251a.

In addition, the second thickness T2 of the plurality of fourth AlGaAs-based layers 251d may gradually decrease from the second AlGaAs-based layer 251b toward the first AlGaAs-based layer 251a.

For example, the plurality of fourth AlGaAs-based layers 251d include a fourth-first AlGaAs-based layer 251d1, a fourth-second AlGaAs-based layer 251d2, a fourth-third AlGaAs-based layer 251d3, and a fourth-fourth AlGaAs-based layer 251d4, and there is complex technical effect in that the plurality of fourth AlGaAs-based layers 251d is formed of 4 nm or less, for example, 1 nm, 2 nm, 3 nm, and 4 nm, respectively, thereby maximizing the tunneling effect to reduce electrical resistance and thermal resistance.

In the embodiment, each of the third AlGaAs-based layer 251c and the fourth AlGaAs-based layer 251d may form one pair and may form 3 to 4 pairs, and the thickness of one pair is controlled to be less than the Bohr radius of about 3 nm to 4 nm to maximize the tunneling effect.

Through this, according to the embodiment, it is possible to maximize the tunneling effect to obtain a complex technical effect of reducing the electrical resistance and the effect of reducing thermal resistance.

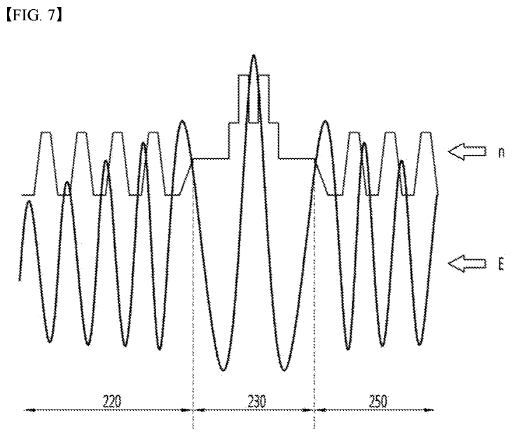

Next, FIG. 7 shows distribution data of a refractive index and light energy in a surface emitting laser device according to an embodiment.

Meanwhile, in FIGS. 5A and 6A, it is illustrated based on the Al composition, but FIG. 7 is a state illustrated based on the refractive index (n).

On the other hand, one of the technical problems of the embodiment is to provide a surface emitting laser device capable of improving light output while improving voltage efficiency and a light emitting device including the same.

Meanwhile, referring to FIG. 4 for a moment, the second reflective layer 250 of the embodiment includes a first group second reflective layer 251 disposed adjacent to the active region 230 and a second group second reflective layer 252 disposed to be spaced apart from the active region 230 than first group second reflective layer 251.

Referring back to FIG. 7, the distribution of light energy E according to the position in the surface emitting laser device according to the embodiment can be seen. The distribution of light energy decreases as the distance from the active region 230 increases. In consideration of the light energy (E) distribution, the concentration of the second conductivity type dopant in the first group second reflective layer 251 may be controlled to be lower than the dopant concentration in the second group second reflective layer 252.

For example, in the embodiment, the concentration of the dopant in the first group second reflective layer 251 may be about 6.00E17 to 5.0E17, and the concentration of the dopant in the second group second reflective layer 252 may be controlled as about 5.0E17 to 1.0E18. In an embodiment. The concentration unit 1.00E18 may mean 1.00×10¹⁸ (atoms/cm³).

Through this, the embodiment can control the concentration of the p-type dopant in the second group second reflective layer 252 to be higher than the dopant concentration in the first group second reflective layer 251 where the first light energy is relatively high. Doping the p-type dopant relatively low in the region of the first group second reflective layer 251 can minimize light absorption in the region of the first group second reflective layer 251, and doping the p-type dopant relatively high in the region of the second group can improve the light output, such that a unique technical effect of providing a surface emitting laser device and a light emitting device including the same capable of simultaneously improving light output and voltage efficiency by improving voltage efficiency and of improving resistance by a relatively high dopant.

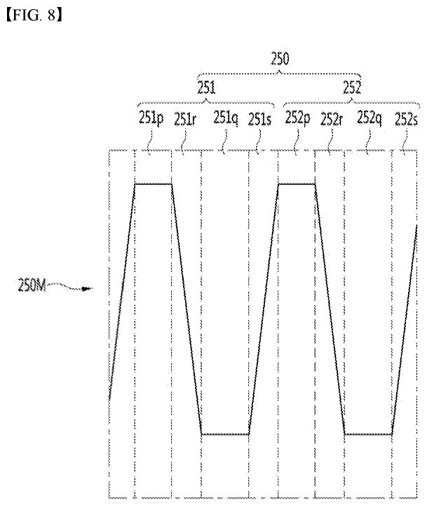

Next, FIG. 8 is an enlarged view of a portion 250M of the second reflective layer of the surface emitting laser device according to the embodiment illustrated in FIG. 4, and is data based on a refractive index n.

Referring to FIG. 8, in an embodiment, the second reflective layer 250 may include a first group second reflective layer 251 and a second group second reflective layer 252.

At this time, the first group second reflective layer 251 may include a plurality of layers, for example, the second-first reflective layer 251p, the second-second reflective layer 251q, and the second-third reflective layer 251r and a second-fourth reflective layer 251s.

In an embodiment, the first group second reflective layer 251 may include a plurality of pairs when the second-first reflective layers 251p to second-fourth reflective layers 251s are used as one pair. For example, in an embodiment, the first group of second reflective layers 251 may include about 2 to 5 pairs of second-first reflective layers 251p to second-fourth reflective layers 251s.

In addition, the second group second reflective layer 252 may include a plurality of layers, for example, the second-fifth reflective layer 252p, the second-sixth reflective layer 252q, and the second-seventh reflective layer 252r, and a second-eight reflective layer 252s.

The second group second reflective layer 252 may also include a plurality of pairs when the second-fifth reflective layers 252p to second-eight reflective layers 252s are used as one pair. For example, in the embodiment, the second group second reflective layer 252 is about 10 to 20 when the second-fifth reflective layers 252p to second-eight reflective layers 252s are used as one pair.

One of the technical problems of the embodiment is to provide a surface emitting laser device capable of improving light output by minimizing the influence of a carrier barrier due to generation of an electric field in a reflective layer, and a light emitting device including the same.

In addition, one of the technical problems of the embodiment is to provide a surface emitting laser device capable of improving light output while improving voltage efficiency and a light emitting device including the same.

Referring to FIG. 8, in an embodiment, the first group second reflective layers 251 include a second-first reflective layer 251p, a second-second reflective layer 251q, a second-third reflective layer 251r, and a second-fourth reflective layer 251s may be included, and each layer may have a different refractive index.

For example, the first group second reflective layer 251 has a second-first reflective layer 251p having a first refractive index, and a second-second reflective layer 251q disposed on one side of second-first reflective layer 251p and the second-first reflective layer 251p has a second refractive index lower than the first refractive index. Also, the first group second reflective layer 251 may include a second-third reflective layer 251r disposed therebetween the second-first reflective layer 251p and the second-second reflective layer 251q, a third refractive index of second-third reflective layer 251r may be between the first and second refractive indexes of the second-first reflective layer 251p and the second-second reflective layer 251q.

For example, the first group second reflective layer 251 has a second-first reflective layer 251p having a first aluminum concentration, and a second-second reflective layer 251q disposed on one side of the reflective layer 251p and a second aluminum concentration of second-second reflective layer 251q is higher than the first aluminum concentration. Also, the first group second reflective layer 251 may include a second-third reflective layer 251r disposed between the second-first reflective layer 251p and the second-second reflective layers 251q, and may have a third aluminum concentration that changes from the first aluminum concentration to the second aluminum concentration.

For example, when the first group second reflective layer 251 includes AlₓGa₍₁₋ₓ₎As(0<x<1), the second-first reflective layer 251p may be Al_{0.12}Ga_{0.88}As, the second-second reflective layer 251q may be Al_{0.88}Ga_{0.12}As, and the second-third reflective layer 251r may be Alₓ₃Ga₍₁₋ₓ₃₎As(0.12<X3<0.88), but is not limited thereto.

In addition, the first group second reflective layer 251 may include a second-fourth reflective layer 251s disposed outside the second-second reflective layer 251q and the second-fourth reflective layer 251s has a fourth aluminum concentration that changes from the first aluminum concentration to the second aluminum concentration.

For example, when the first group second reflective layer 251 includes AlₓGa₍₁₋ₓ₎As(0<x<1), the second-fourth reflective layers 251s may be Alₓ₄Ga₍₁₋ₓ₄₎As(0.12<X4<0.88) may be, but is not limited thereto.

Through this, according to an embodiment, the second-third reflective layer 251r or the second-fourth reflective layer 251s having an aluminum concentration in an intermediate region between the adjacent second-first reflective layer 251p and the second-second reflective layer 251q can minimize the generation of an electric field due to energy band bending at the interface between adjacent reflective layers, thereby lowering the carrier barrier and improving light output.

Accordingly, according to the embodiment, it is possible to provide a surface emitting laser device capable of improving light output by minimizing the influence of a carrier barrier due to generation of an electric field in a reflective layer, and a light emitting device including the same.

Also, in an embodiment, the thickness of the second-second reflective layer 251q may be thicker than the thickness of the second-first reflective layer 251p. In addition, the thickness of the second-first reflective layer 251p or the second-second reflective layer 251q may be thicker than that of the second-third reflective layer 251r or the second-fourth reflective layer 251s.

In this case, the second aluminum concentration of the second-second reflective layer 251q may be high in the first aluminum concentration of the second-first reflective layer 251p. In addition, the first aluminum concentration of the second-first reflective layer 251p may be higher than the third aluminum concentration of the second-third reflective layer 251r or the fourth aluminum concentration of the second-fourth reflective layer 251s.

Accordingly, since the thickness of the second-second reflective layer 251q having a relatively high aluminum concentration is thicker than the thickness of the second-first reflective layer 251p, the grating quality may be improved, thereby contributing to light output.

In addition, since the thickness of the second-first reflective layer 251p, which has a relatively high aluminum concentration, is thicker than the thickness of the second-third reflective layer 251r or the second-fourth reflective layer 251s, it will contribute to light output by improving the lattice quality.

For example, the thickness of the second-second reflective layer 251q may be about 50 to 55 nm, the thickness of the second-first reflective layer 251p may be about 26 to 32 nm. Since the thickness of the second-second reflective layer 251q is thicker than the thickness of the second-first reflective layer 251p and the aluminum concentration of the second-second reflective layer 251q is relatively high, it is possible to improve the grating quality and contribute to light output.

In addition, the thickness of the second-third reflective layer 251r may be about 22 to 27 nm, the thickness of the second-fourth reflective layer 251s may be about 22 to 27 nm. Since the thickness of the second-second reflective layer 251q and the second-first reflective layer 251p is thicker than that of the second-third reflective layer 251r and the second-fourth reflective layer 251s and the aluminum concentration of the second-second reflective layer 251q is relatively high, it is possible to contribute to light output by improving the lattice quality.

With continued reference to FIG. 8, in an embodiment, the second group second reflective layer 252 includes a second-fifth reflective layer 252p, a second-sixth reflective layer 252q, a second-seventh reflective layer 252r, and second-eight reflective layer 252s, and each layer may have a different refractive index.

For example, the second group second reflective layer 252 may include a second-fifth reflective layer 252p having a fifth refractive index and a second-sixth reflective layer 252q having a sixth refractive index lower than the fifth refractive index, a second-seventh reflective layer 252r disposed between the second-fifth reflective layer 252p and a second-sixth reflective layer 252q, having a seventh refractive index between the fifth and sixth refractive indexes of the second-fifth reflective layer 252p and the second-sixth reflective layer 252q.

For example, the second group second reflective layer 252 may include a second-fifth reflective layer 252p having a fifth aluminum concentration and a second-sixth reflective layer 252q having a sixth aluminum concentration higher than the fifth aluminum concentration, a second-seventh reflective layer 252r disposed between the second-fifth reflective layer 252p and a second-sixth reflective layer 252q, having a seventh aluminum concentration hat changes from the fifth aluminum concentration to the sixth aluminum concentration.

For example, when the second group second reflective layer 252 includes AlₓGa₍₁₋ₓ₎As(0<x<1), the second-fifth reflective layer 252p can be Al_{0.12}Ga_{0.88}As. The second-sixth reflective layer 252q can be Al_{0.88}Ga_{0.12}As, and the second-seventh reflective layer 252r can be Alₓ₃Ga₍₁₋ₓ₃₎As(0.12<X3<0.88), but is not limited thereto.

In addition, the second group second reflective layer 252 may include a second-eight reflective layer 252s disposed outside the second-sixth reflective layer 252q, having an eighth aluminum concentration that changes from a fifth aluminum concentration to the sixth aluminum concentration.

For example, when the second group second reflective layer 252 includes AlₓGa₍₁₋ₓ₎As(0<x<1), the second-eight reflective layers 252s may be Alₓ₄Ga₍₁₋ₓ₄₎As(0.12<X4<0.88) may be, but is not limited thereto.

Through this, according to the embodiment, the second-seventh reflective layer 252r or the second-eight reflective layer 252s having an aluminum concentration in the intermediate region between the adjacent second-fifth reflective layer 252p and second-sixth reflective layer 252q can minimize the generation of an electric field caused by energy band bending at the interface between adjacent reflective layers, thereby lowering the carrier barrier and improving light output.

Accordingly, according to the embodiment, it is possible to provide a surface emitting laser device capable of improving light output by minimizing the influence of a carrier barrier due to generation of an electric field in a reflective layer, and a light emitting device including the same.

In addition, in the embodiment, the thickness of the second-sixth reflective layer 252q may be thicker than the thickness of the second-fifth reflective layer 252p. Further, the thickness of the second-fifth reflective layer 252p or the second-sixth reflective layer 252q may be thicker than that of the second-seventh reflective layer 252r or the second-eight reflective layer 252s.

In this case, the sixth aluminum concentration of the second-sixth reflective layers 252q may be higher than the fifth aluminum concentration of the second-fifth reflective layers 252p. In addition, the fifth aluminum concentration of the second-fifth reflective layers 252p may be higher than the seventh aluminum concentration of the second-seventh reflective layers 252r or the eighth aluminum concentration of the second-eight reflective layers 252s.

Accordingly, since the thickness of the second-sixth reflective layer 252q having a relatively high aluminum concentration is thicker than the thickness of the second-fifth reflective layer 252p, the grating quality may be improved to contribute to light output.

In addition, since the thickness of the second-fifth reflective layer 252p, which has a relatively high aluminum concentration, is thicker than the thickness of the second-seventh reflective layer 252r or the second-eight reflective layer 252s, it can contribute to light output by improving the lattice quality.

For example, the thickness of the second-sixth reflective layer 252q may be about 50 to 55 nm, the thickness of the second-fifth reflective layer 252p may be about 40 to 45 nm, and the aluminum concentration of the second-sixth reflective layer 252q is relatively high. Since the thickness of the second-sixth reflective layer 252q is thicker than the thickness of the second-fifth reflective layer 252p, the grating quality may be improved, thereby contributing to light output.

Further, the thickness of the second-seventh reflective layer 252r may be about 22 to 27 nm, the thickness of the second-eight reflective layer 252s may be about 22 to 27 nm, and the aluminum concentration of the second-sixth reflective layers 252q and second-fifth reflective layers 252p are relatively high. Since the thicknesses of the second-sixth reflective layers 252q and second-fifth reflective layers 252p are thicker than those of the second-seventh reflective layers 252r and second-eight reflective layers 252s, the grating quality can be improved to contribute to light output.

According to the related art, there is a possibility that a standing wave is absorbed by such a dopant to proceed at an interface with the DBR. Accordingly, the embodiment minimizes resistance by performing more doping at the node position where the optical power reflectance of the standing wave is the smallest, and performing light doping as low as possible at the antinode position such that there is a technical effect that can minimize absorption. The node position may mean a point at which the refractive index of each layer increases or decreases to change.

Referring to FIG. 8, the refractive indices of the second-first reflective layer 251p and the second-second reflective layer 251q in the first group second reflective layer 251 are the anti-node positions that do not change to the upper or lower point. In addition, in the first group second reflective layer 251, the refractive indices of the second-third reflective layers 251r and the second-fourth reflective layers 251s may be a node position that changes by rising or falling.

Accordingly, in the embodiment, the second conductivity type doping concentration of the second-third reflective layer 251r or the second-fourth reflective layer 251s can be controlled higher than the conductivity type doping concentration of the second of the second-first reflective layer 251p or the second-second reflective layer 251q.

For example, the second conductivity type doping concentration of the second-third reflective layer 251r or the second-fourth reflective layer 251s may be about 1.00E18 to 1.50E18, and the second conductivity type doping concentration of the second-first reflective layer 251p or the second-second reflective layer 251q may be about 6.00E17 to 8.00E17.

Accordingly, in the second-third reflective layer 251r or the second-fourth reflective layer 251s, which is a node position having a low optical power reflectance of the standing wave, a lot of doping is performed to minimize resistance, and there is a complex technical effect in that can minimize light absorption by performing low doping at the second-first reflective layer 251p or the second-second reflective layer 251q, which is an antinode position,

In addition, in the embodiment, among the second-third reflective layers 251r or second-fourth reflective layers 251s, which are the node positions, the second-fourth reflective layer 251s, which is the node position whose refractive index increases in a direction away from the active region 230, the concentration of the second conductivity type dopant may be controlled to be higher than the concentration of the second conductivity type dopant in the second-third reflective layer 251r, which is a node position at which the refractive index decreases.

Through this, the concentration of the second conductivity type dopant of the second-fourth reflective layer 251s, which is a node position at which the refractive index having a relatively lower optical reflectivity is increased, can be controlled to be high, thereby improving electrical characteristics.

Referring to FIG. 8, in the second group second reflective layer 252, the refractive indices of the second-fifth reflective layer 252p and the second-sixth reflective layer 252q are anti-node positions that do not change to the upper or lower point. In addition, in the second group second reflective layer 252, refractive indices of the second-seventh reflective layers 252r and second-eight reflective layers 252s may be a node position that changes by rising or falling.

In the embodiment, the second conductivity type doping concentration of the second-seventh reflective layer 252r or the second-eight reflective layer 252s can be controlled higher than the doping concentration of the second conductivity type of the second-fifth reflective layer 252p or the second-sixth reflective layer 252q.

Accordingly, the second-seventh reflective layer 252r or the second-eight reflective layer 252s, which is a node position having a low optical power reflectance of the standing wave, undergoes a lot of doping to minimize resistance and the second-fifth reflective layer 252p or the second-sixth reflective layer 252q, which is an antinode position, has a complex technical effect that can minimize light absorption by performing low doping.

In addition, in the embodiment, among the second-seventh reflective layers 252r or second-eight reflective layers 252s, which are the node positions, the second-eight reflective layer 252s, which is the node position whose refractive index increases in a direction away from the active region 230, the concentration of the second conductivity type dopant may be controlled to be higher than the concentration of the second conductivity type dopant in the second-seventh reflective layer 252r, which is a node position at which the refractive index decreases.

Through this, the concentration of the second conductivity type dopant of the second-eight reflective layers 252s, which is the node position at which the refractive index having a relatively lower optical reflectivity is increased, may be controlled to be high, thereby improving electrical characteristics.

According to the embodiment, by controlling the concentration of the second conductivity type dopant in the second-fourth reflective layer, which is the node position where the refractive index is relatively lower in optical reflectivity, it is possible to provide a surface emitting laser device and a light emitting device including the same capable of increasing the concentration of the second conductivity type dopant to improve the electrical characteristics, and improving the voltage efficiency while the light output being also improved.

<Active Region>

Referring back to FIG. 4, the active region 230 may be disposed between the first reflective layer 220 and the second reflective layer 250.

The active region 230 may include an active layer 232 and at least one or more cavities 231 and 233. For example, the active region 230 may include an active layer 232, a first cavity 231 disposed below the active layer 232, and a second cavity 233 disposed above the active layer 232. The active region 230 of the embodiment may include both the first cavity 231 and the second cavity 233, or may include only one of them.

The active layer 232 may include any one of a single well structure, a multiple well structure, a single quantum well structure, a multi quantum well (MQW) structure, a quantum dot structure, or a quantum wire structure.

The active layer 232 may include a quantum well layer 232a and a quantum barrier layer 232b using a compound semiconductor material of a group III-V element. The quantum well layer 232a may be formed of a material having an energy band gap smaller than the energy band gap of the quantum barrier layer 232b. The active layer 232 may be formed in a 1 to 3 pair structure such as InGaAs/AlxGaAs, alGaInP/GaInP, alGaAs/AlGaAs, alGaAs/GaAs, GaAs/InGaAs, but is not limited thereto. A dopant may not be doped into the active layer 232.

Next, the first cavity 231 and the second cavity 233 may be formed of an Al_{y}Ga_{(1-y)}As(0<y<1) material, but are not limited thereto. For example, the first cavity 231 and the second cavity 233 may each include a plurality of layers of Al_{y}Ga_{(1-y)}As.

For example, the first cavity 231 may include a first-first cavity layer 231a and a first-second cavity layer 231b. The first-first cavity layer 231a may be further spaced apart from the active layer 232 than the first-second cavity layer 231b. The first-first cavity layer 231a may be formed to be thicker than the first-second cavity layer 231b, but is not limited thereto.

For example, the first-first cavity layer 231a may be formed to be about 60 to 70 nm, and the first-second cavity layer 231b may be formed to be about 40 to 55 nm, but the present invention is not limited thereto.

In addition, the second cavity 233 may include a second-first cavity layer 233a and a second-second cavity layer 233b. The second-second cavity layer 233b may be further spaced apart from the active layer 232 compared to the second-first cavity layer 233a. The second-second cavity layer 233b may be formed to be thicker than the second-first cavity layer 233a, but is not limited thereto. For example, the second-second cavity layer 233b may be formed to be about 60 to 70 nm, and the second-first cavity layer 233a may be formed to be about 40 to 55 nm, but are not limited thereto.

<Aperture Region>

Referring back to FIG. 3, in an embodiment, the aperture region 240 may include an insulating region 242 and an aperture 241. The aperture 241 may be referred to as an opening, and the aperture region 240 may be referred to as an opening region.

The insulating region 242 may be formed of an insulating layer, for example, Aluminum oxide, and may function as a current blocking region, and an aperture 241 that is a light emission region may be defined by the insulating region 242.

For example, when the aperture region 240 includes aluminum gallium arsenide (AlGaAs), the AlGaAs of the aperture region 240 reacts with H₂O and the edge is changed to aluminum oxide (Al₂O₃). Accordingly, the insulating region 242 may be formed, and the central region that does not react with H₂O may be an aperture 241 made of AlGaAs.

According to the embodiment, light emitted from the active region 230 through the aperture 241 may be emitted to the upper region, and the aperture 241 may have excellent light transmittance compared to the insulating region 242.

Referring to FIG. 4, the insulating region 242 may include a plurality of layers. For example, the insulating region 242 may include a first insulating layer 242a and a second insulating layer 242b. The first insulating layer 242a may have a thickness equal to or different from that of the second insulating layer 242b.

<Second Electrode, Ohmic Contact Layer, Passivation Layer>

Referring to FIG. 3, the surface emitting laser device 201 according to the embodiment may be mesa etched from the second reflective layer 250 to the aperture region 240 and the active region 230 to define an emitter. Also, a part of the first reflective layer 220 may be mesa etched.

A second electrode 280 may be disposed on the second reflective layer 250, and the second electrode 280 may include a contact electrode 282 and a pad electrode 284.

A passivation layer 270 may be disposed in an area between the contact electrodes 282 and the second reflective layer 250, and an exposed area of the second reflective layer 250 may correspond to the above-described aperture 241. The contact electrode 282 may improve ohmic contact characteristics between the second reflective layer 250 and the pad electrode 284.

The second electrode 280 may be made of a conductive material, and may be, for example, a metal. For example, the second electrode 280 includes at least one of aluminum (Al), titanium (Ti), chromium (Cr), nickel (Ni), copper (Cu), and gold (Au) and can be formed into a structure.

In FIG. 3, a passivation layer 270 may be disposed on side surfaces and top surfaces of the light emitting structure mesa etched and on the top surface of the first reflective layer 220. The passivation layer 270 is also disposed on a side surface of the surface emitting laser device 201 separated by device units, and protects and insulates the surface emitting laser device 201. The passivation layer 270 may be made of an insulating material, for example, a nitride or an oxide. For example, the passivation layer 270 may include at least one of polyimide, silica (SiO₂), or silicon nitride (Si₃N₄).

The passivation layer 270 may be thinner than the contact electrode 282 on the upper surface of the light emitting structure, and the contact electrode 282 may be exposed above the passivation layer 270 through this. The pad electrode 284 may be disposed in electrical contact with the exposed contact electrode 282, and the pad electrode 284 may extend and be disposed above the passivation layer 270 to receive current from the outside.

(Manufacturing Method)

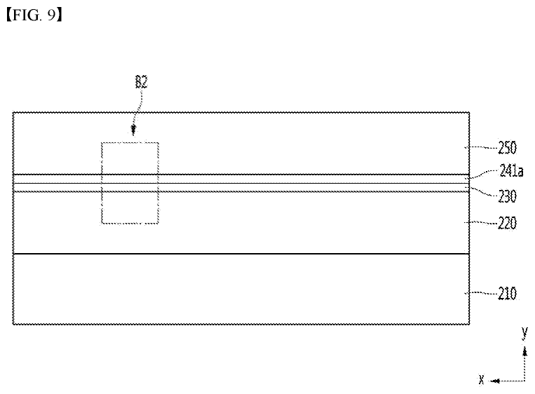

Hereinafter, a method of manufacturing a surface emitting laser device according to an embodiment will be described with reference to FIGS. 9 to 16B.

First, as shown in FIG. 9, a light emitting structure including a first reflective layer 220, an active region 230, and a second reflective layer 250 are formed on a substrate 210.

The substrate 210 may be formed of a material suitable for growth of semiconductor materials or a carrier wafer, may be formed of a material having excellent thermal conductivity, and may include a conductive substrate or an insulating substrate.

For example, when the substrate 210 is a conductive substrate, a metal having excellent electrical conductivity can be used, and since it can sufficiently dissipate heat generated when the surface emitting laser device 200 is operated, a GaAs substrate having high thermal conductivity, alternatively, a metal substrate or a silicon (Si) substrate may be used.

In addition, when the substrate 210 is a non-conductive substrate, an AlN substrate, a sapphire (Al₂O₃) substrate, or a ceramic-based substrate may be used.

In addition, in the exemplary embodiment, the same type of substrate as the first reflective layer 220 may be used as the substrate 210. For example, when the substrate 210 is a GaAs substrate of the same kind as the first reflective layer 220, the first reflective layer 210 and the lattice constant match, so that defects such as lattice mismatch do not occur in the first reflective layer 220.

Next, the first reflective layer 220 may be formed on the substrate 210, and FIG. 10 is an enlarged cross-sectional view of the second area B2 of the surface emitting laser device according to the embodiment illustrated in FIG. 9.

Hereinafter, a surface emitting laser device according to an exemplary embodiment will be described with reference to FIGS. 9 and 10 together.

The first reflective layer 220 may be grown using a method such as chemical vapor deposition (CVD), molecular beam epitaxy (MBE), sputtering, or hydroxide vapor phase epitaxy (HVPE).

The first reflective layer 220 may be doped with a first conductivity type. For example, the first conductivity-type dopant may include an n-type dopant such as Si, Ge, Sn, Se, and Te.

The first reflective layer 220 may include a gallium-based compound, for example, AlGaAs, but is not limited thereto. The first reflective layer 220 may be a Distributed Bragg Reflector (DBR). For example, the first reflective layer 220 may have a structure in which layers made of materials having different refractive indices are alternately stacked at least once or more.

For example, as shown in FIG. 10, the first reflective layer 220 includes a first group first reflective layer 221 on the substrate 210 and a second group first reflective layer 222 is disposed on the first group first reflective layer 221.

The first group first reflective layer 221 and the second group first reflective layer 222 include a plurality of layers made of a semiconductor material having a composition formula of AlₓGa₍₁₋ₓ₎As(0<x<1). If Al in each layer increases, the refractive index of each layer decreases, and when Ga increases, the refractive index of each layer may increase.

In addition, as shown in FIG. 10, the first group first reflective layer 221 and the second group first reflective layer 222 may be formed of a single layer or a plurality of layers, respectively. For example, the first group first reflective layer 221 may include about 30 to 40 pairs of the first group first-first layer 221a and the first group first-second layer 221b. In addition, the second group first reflective layer 222 may also include about 5 to 15 pairs of the second group first-first layer 222a and the second group first-second layer 222b.

Next, an active region 230 may be formed on the first reflective layer 220.

Referring to FIG. 10, the active region 230 may include an active layer 232, a first cavity 231 disposed below the active layer 232, and a second cavity 233 disposed above the active layer 232. The active region 230 of the embodiment may include both the first cavity 231 and the second cavity 233, or may include only one of them.

The active layer 232 may include a quantum well layer 232a and a quantum barrier layer 232b using a compound semiconductor material of a group III-V element. The active layer 232 may be formed in a 1 to 3 pair structure such as InGaAs/AlxGaAs, alGaInP/GaInP, alGaAs/AlGaAs, alGaAs/GaAs, GaAs/InGaAs, but is not limited thereto. A dopant may not be doped into the active layer 232.

The first cavity 231 and the second cavity 233 may be formed of an Al_{y}Ga_{(1-y)}As (0<y<1) material, but are not limited thereto. For example, the first cavity 231 and the second cavity 233 may each include a plurality of layers of Al_{y}Ga_{(1-y)}As.

For example, the first cavity 231 may include a first-first cavity layer 231a and a first-second cavity layer 231b. In addition, the second cavity 233 may include a second-first cavity layer 233a and a second-second cavity layer 233b.

Next, an AlGa-based layer 241a for forming the aperture region 240 may be formed on the active region 230. The AlGa-based layer 241a may include a plurality of layers. For example, the AlGa-based layer 241a may include a first AlGa-based layer 241a1 and a second AlGa-based layer 241a2.

The AlGa-based layer 241a may include a material such as Al_{z}Ga_{(1-z)}As (0<z<1), but is not limited thereto.

The AlGa-based layer 241a may include a conductive material, and may include the same material as the first reflective layer 220 and the second reflective layer 250, but is not limited thereto.

For example, when the AlGa-based layer 241a includes an AlGaAs-based material, the AlGa-based layer 241a is a semiconductor material having a composition formula of AlₓGa₍₁₋ₓ₎As (0<x<1). It may be made of, for example, Al_{0.98}Ga_{0.02}As may have a composition formula, but is not limited thereto.

Next, a second reflective layer 250 may be formed on the AlGa-based layer 241a.

The second reflective layer 250 may include a gallium-based compound, for example, AlGaAs. For example, each layer of the second reflective layer 250 may include AlGaAs, and in detail, may be formed of a semiconductor material having a composition formula of AlₓGa₍₁₋ₓ₎As (0<x<1).

The second reflective layer 250 may be doped with a second conductivity type dopant. For example, the second conductivity-type dopant may be a p-type dopant such as Mg, Zn, Ca, Sr, Ba, or the like.

The second reflective layer 250 may also be a Distributed Bragg Reflector (DBR). For example, the second reflective layer 250 may have a structure in which a plurality of layers made of materials having different refractive indices are alternately stacked at least once or more.

For example, the second reflective layer 250 includes a first group second reflective layer 251 disposed adjacent to the active region 230 and a second group second reflective layer 252 spaced apart from the active region 230 than the first group second reflective layer 251.

In addition, the first group second reflective layer 251 and the second group second reflective layer 252 may be formed of a single layer or a plurality of layers, respectively. For example, the first group second reflective layer 251 may include about 1 to 5 pairs of the first group second-first layer 251a and the first group second-second layer 251b. In addition, the second group second reflective layer 252 may also include about 5 to 15 pairs of the second group second-first layer 252a and the second group second-second layer 252b.

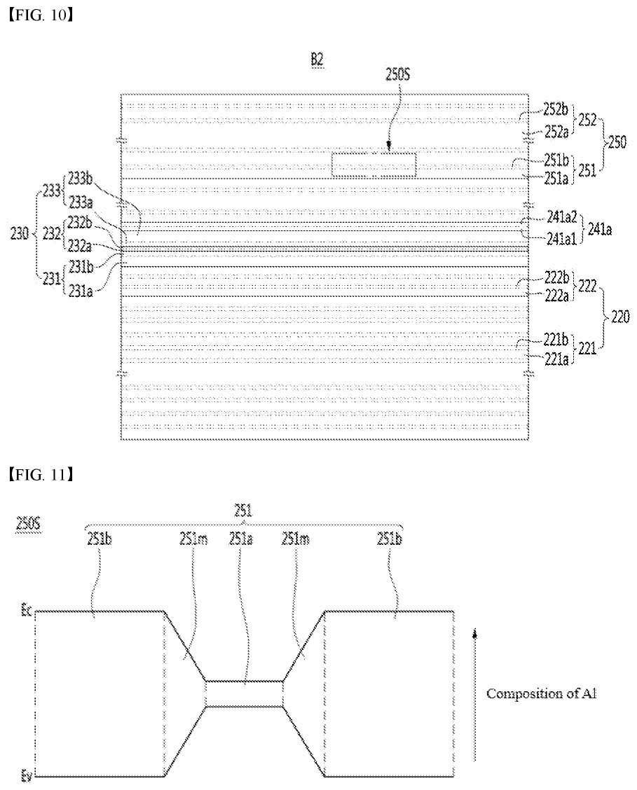

Next, FIG. 11 is a first energy band diagram for the first region 250S of the second reflective layer of the surface emitting laser device according to the embodiment illustrated in FIG. 10.

The following description will be described centering on the second reflective layer 250, but the technical features of the embodiment may be applied to the first reflective layer 220 as well.

Referring to FIG. 11, the first group second reflective layer 251 according to the embodiment may include a plurality of layers. For example, the first group second reflective layer 251 of the embodiment may include a first AlGaAs-based layer 251a and a second AlGaAs-based layer 251b, and a grading AlGaAs-based layer 251m therebetween.

For example, when the first group second reflective layer 251 includes AlₓGa₍₁₋ₓ₎As (0<x<1), the first group second reflective layer 251 includes a first AlGaAs-based layer 251a having composition of Alₓ₁Ga₍ᵢ₋ₓ₁₎As (however, 0<X1<0.2), a second AlGaAs-based layer 251b having composition of Alₓ₂Ga₍₁₋ₓ₂₎As (however, 0.8<X2<1.0), and a graded AlGaAs-based layer 251m including Al_{y1}Ga_{(1-y1)}(however, X1<y1<X2) there between.

Through this, according to an embodiment, a grading AlGaAs-based layer 251m having an aluminum concentration is provided in an intermediate region between the adjacent first AlGaAs-based layer 251a and the second AlGaAs-based layer 251b such that there is a technical effect of improving light output by minimizing the generation of an electric field due to energy band bending and lowering a carrier barrier at the interface between adjacent reflective layers.

Next, one of the technical problems of the embodiment is to provide a surface emitting laser device and a light emitting device including the same, which can improve light efficiency by not generating thermal resistance while improving electrical properties.

As described above, according to the internal technology, there is an attempt to lower the electrical resistance at the interface between the DBR layers, but this attempt causes a problem of lowering the optical efficiency due to the increase in thermal resistance in the DBR layer, which is technical contradiction.

For example, as shown in FIG. 5B, according to a internal technology, when a grading AlGaAs-based layer 251m is inserted at the high/low refractive index interface to reduce electrical resistance in the DBR layer, the Al composition is in the range of about 20 to 80% (Xt). Thermal resistance increases due to alloy scattering. Accordingly, according to the application of the graded AlGaAs-based layer 251m inserted to reduce electrical resistance, there is a technical contradiction in which optical efficiency is lowered due to the generation of thermal resistance.

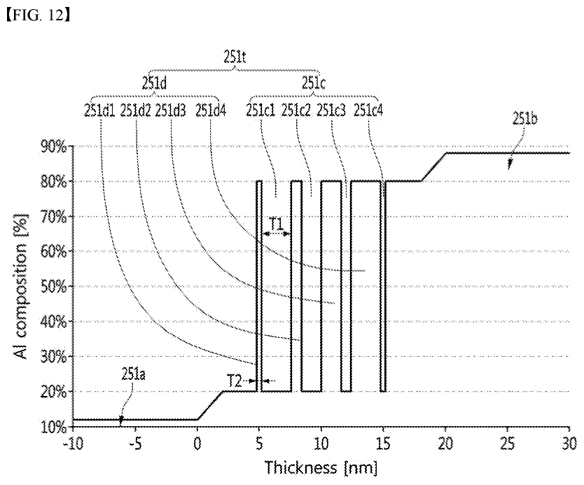

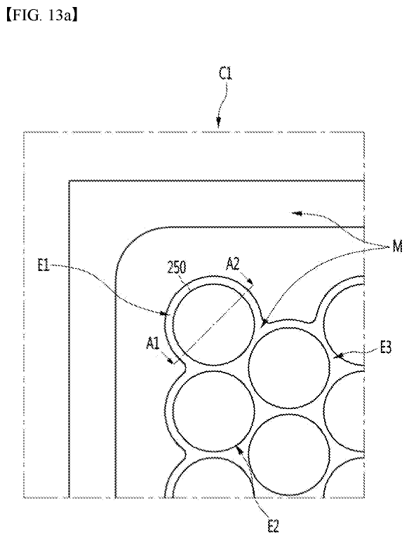

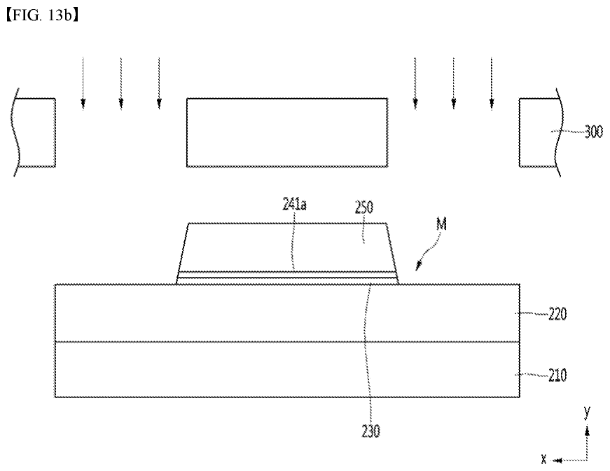

FIG. 12 is a partially enlarged view of a second reflective layer of a surface emitting laser device according to an embodiment.

Referring to FIG. 12, the second reflective layer 250 according to the embodiment may include an AlGaAs-based transition region 251t disposed between the first AlGaAs-based layer 251a and the second AlGaAs-based layer 251b.

The second reflective layer 250 of the embodiment includes a first AlGaAs-based layer 251a containing Alₓ₁Ga₍₁₋ₓ₁₎As (however, 0<X1<0.2), and a second AlGaAs-based layer 251b containing Alₓ₂Ga₍₁₋ₓ₂₎ As (however, 0.8<X2<1.0) on the first AlGaAs-based layer 251a. An AlGaAs-based transition region 251t disposed between the first AlGaAs-based layer 251a and the second AlGaAs-based layer 251b may be included.

In this case, in the embodiment, the AlGaAs-based transition region 251t includes a third AlGaAs-based layer 251c containing Alₓ₃Ga₍₁₋ₓ₃₎As (however, 0<X3<0.2) and a fourth AlGaAs-based layer 251d containing Alₓ₄Ga₍₁₋ₓ₄₎As (however, 0.8<X4<1.0), and the third AlGaAs-based layer 251c and the fourth AlGaAs-based layer 251d are alternately formed and the layers of can be arranged.

According to an embodiment, the Al concentration (X3) of the third AlGaAs-based layer 251c is higher than the Al concentration (X1) of the first AlGaAs-based layer 251a but is controlled to 20% or less. The Al concentration (X4) of the fourth AlGaAs-based layer 251d is lower than the Al concentration (X2) of the second AlGaAs-based layer 251b, but is controlled to be 80% or more such that thermal resistance can be prevented from being generated.

For example, in the embodiment, the AlGaAs-based transition region 251t has a third AlGaAs-based layer 251c of Alₓ₃Ga₍₁₋ₓ₃₎As (however, X1<X3<0.2) having low thermal resistance. A fourth AlGaAs-based layer 251d of low Alₓ₄Ga₍₁₋ₓ₄₎As (however, 0.8<X4<X2) is included. The AlGaAs-based transition region 251t can be disposed between the first AlGaAs-based layer 251a And the second AlGaAs-based layer 251b, so that thermal resistance is not generated, thereby improving light efficiency and improving electrical characteristics.

For example, in the high current region of 2,000 mA to 2,500 mA or more as shown in FIG. 6B, optical power is significantly lowered due to the generation of thermal resistance as in Comparative Example (R). However according to embodiment Example (E), the AlGaAs series transition region 251t is disposed between the first AlGaAs-based layer 251a and the second AlGaAs-based layer 251b so that thermal resistance is not generated, thereby improving light efficiency and improving electrical characteristics.

Referring back to FIG. 12, according to an embodiment, the Al concentration (X3) of the third AlGaAs-based layer 251c may be controlled to 8% to 20% or less, preferably 12% to 20% or less. Through this, the Al concentration (X3) of the third AlGaAs-based layer 251c is controlled to be 20% or less so that thermal resistance can be prevented, and the Al concentration of the third AlGaAs-based layer 251c (X3) is controlled to be 8% or more and is controlled to be higher than the Al concentration (X1) of the first AlGaAs-based layer 251a, thereby minimizing the difference with the Al concentration (X4) of the fourth AlGaAs-based layer 251d to be formed thereafter. There is a technical effect of maintaining or improving crystal quality or electrical resistance characteristics while lowering thermal resistance.

In addition, the concentration (X4) of Al in the fourth AlGaAs-based layer 251d may be controlled to 80% to 92% or less, preferably 80% to 88% or less. Through this, the Al concentration (X4) of the fourth AlGaAs-based layer 251d can be controlled to be 80% or more to prevent thermal resistance from being induced, and the Al concentration of the fourth AlGaAs-based layer 251d (X4) is controlled to be less than 92% and is controlled to be lower than the Al concentration (X4) in the fourth AlGaAs-based layer 251d, thereby minimizing the difference with the Al concentration (X3) in the third AlGaAs-based layer 251c to be formed later. There is a technical effect of maintaining or improving crystal quality or electrical resistance characteristics while lowering thermal resistance.

Referring to FIG. 12, the thickness of the AlGaAs-based transition region 251t in the second reflective layer 250 may be thinner than each of the first AlGaAs-based layer 251a and the second AlGaAs-based layer 251b. That is, the thickness of each of the first AlGaAs-based layer 251a and the second AlGaAs-based layer 251b may be thicker than the thickness of the AlGaAs-based transition region 251t.

For example, each of the first AlGaAs-based layer 251a and the second AlGaAs-based layer 251b may have a thickness in a range of 2 to 3 times greater than the thickness of the AlGaAs-based transition region 251t.

For example, the thickness of the AlGaAs-based transition region 251t may be about 15 nm to 28 nm, and the thickness of each of the first AlGaAs-based layer 251a and the second AlGaAs-based layer 251b is about 30 nm to 84 nm, but is not limited thereto.

According to the embodiment, the thickness of the AlGaAs-based transition region 251t is formed to be thinner than each of the first AlGaAs-based layer 251a and the second AlGaAs-based layer 251b. There is a technical effect of minimizing the generation of resistance to improve light efficiency and to improve electrical characteristics.

In addition, in an embodiment, a first thickness T1 of the plurality of third AlGaAs-based layers 251c may be reduced in a direction from the first AlGaAs-based layer 251a to the second AlGaAs-based layer 251b.

In addition, the first thickness T1 of the plurality of third AlGaAs-based layers 251c may gradually decrease from the first AlGaAs-based layer 251a to the second AlGaAs-based layer 251b.

For example, the plurality of third AlGaAs-based layers 251c include a third-first AlGaAs-based layer 251c1, a third-second AlGaAs-based layer 251c2, a third-third AlGaAs-based layer 251c3, and a third-fourth AlGaAs-based layer 251c4, and which are formed of 4 nm or less, for example, 4 nm, 3 nm, 2 nm and 1 nm, respectively, such that complex technical effects can be obtained for maximizing the tunneling effect to reduce electrical resistance and thermal resistance.

In addition, the plurality of fourth AlGaAs-based layers 251d may be thinner in a direction from the second AlGaAs-based layer 251b to the first AlGaAs-based layer 251a.

In addition, the thickness of the plurality of fourth AlGaAs-based layers 251d may gradually decrease from the second AlGaAs-based layer 251b toward the first AlGaAs-based layer 251a.

For example, the plurality of fourth AlGaAs-based layers 251d include a fourth-first AlGaAs-based layer 251d1, a fourth-second AlGaAs-based layer 251d2, a fourth-third AlGaAs-based layer 251d3, and a fourth-fourth AlGaAs-based layer 251d4 may be included, and which are formed of 4 nm or less, for example, 1 nm, 2 nm, 3 nm, and 4 nm, respectively, such that complex technical effects can be obtained for maximizing the tunneling effect to reduce electrical resistance and thermal resistance.

In the embodiment, each of the third AlGaAs-based layer 251c and the fourth AlGaAs-based layer 251d may form one pair and may form 3 to 4 pairs, and the thickness of one pair is controlled to be less than the Bohr radius of 3 nm to 4 nm to maximize the tunneling effect.

Through this, according to the embodiment, it is possible to maximize the tunneling effect to obtain a complex technical effect of the effect of reducing the electrical resistance and the effect of reducing thermal resistance.

Next, FIG. 13A is an enlarged view of the first area C1 of the surface emitting laser device according to the embodiment, and FIG. 13B is a cross-sectional view taken along line A1-A2 of the surface emitting laser device according to the embodiment shown in FIG. 13A.

In the embodiment, as shown in FIG. 13B, a mesa region M may be formed by etching a light emitting structure using a predetermined mask 300. In this case, from the second reflective layer 250 to the AlGa-based layer 241a and the active region 230 may be mesa etched, and a portion of the first reflective layer 220 may be mesa etched. In mesa etching, the AlGa-based layer 241a and the active region 230 can be removed from the second reflective layer 250 in the peripheral region by an inductively coupled plasma (ICP) etching method, and the side of the mesa etch region has a slope.

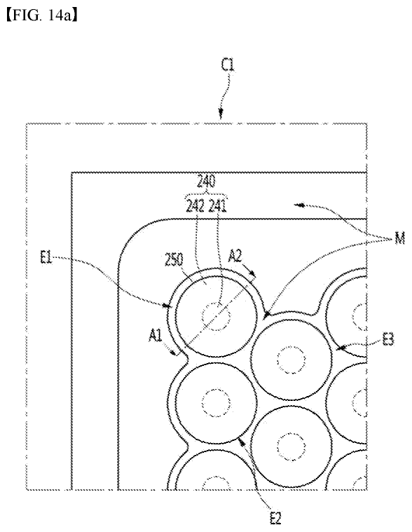

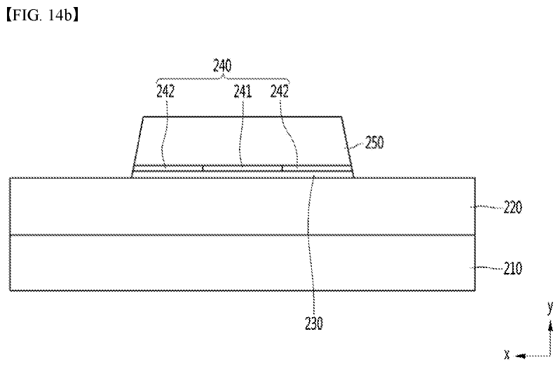

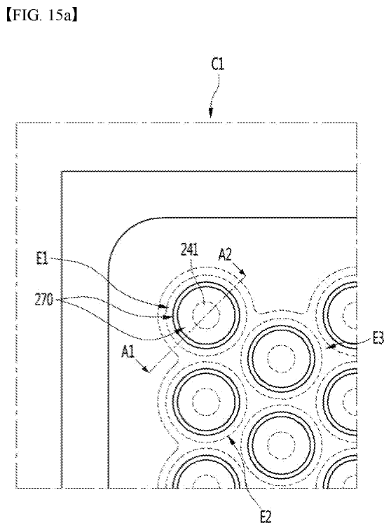

Next, FIG. 14A is an enlarged view of the first area C1 of the surface emitting laser device according to the embodiment, and FIG. 14B is a cross-sectional view taken along line A1-A2 of the surface emitting laser device according to the embodiment shown in FIG. 14A.

In the embodiment, as shown in FIG. 14B, the edge region of the AlGa-based layer 241a may be changed to the insulating region 242, for example, it may be changed by wet oxidation. Through this, the aperture region 240 including the insulating region 242 and the aperture 241 that is a non-oxidized region may be formed.

For example, when oxygen is supplied from the edge region of the AlGa-based layer 241a, alGaAs of the AlGa-based layer reacts with H₂O to form aluminum oxide (Al₂O₃). At this time, the reaction time and the like are adjusted so that the central region of the AlGa-based layer does not react with oxygen and only the edge region reacts with oxygen to form the insulating region 242 of aluminum oxide.

In addition, the embodiment may change the edge region of the AlGa-based layer to the insulating region 242 through ion implantation, but is not limited thereto. During ion implantation, photons may be supplied with an energy of 300 keV or more.

After the above-described reaction process, conductive AlGaAs may be disposed in the central region of the aperture region 240 and non-conductive Al₂O₃ may be disposed in the edge region. The AlGaAs in the central region is a portion in which light emitted from the active region 230 proceeds to the upper region, and may be defined as an aperture 241.

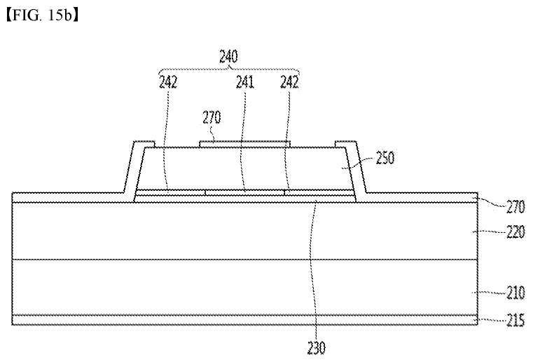

Next, FIG. 15A is an enlarged view of a first area C1 of the surface emitting laser device according to the embodiment, and FIG. 15B is a cross-sectional view along line A1-A2 of the surface emitting laser device according to the embodiment shown in FIG. 15A.

FIG. 15B, a passivation layer 270 may be formed on the upper surface of the light emitting structure. The passivation layer 270 may include at least one of polymide, silica (SiO₂), or silicon nitride (Si₃N₄).

The passivation layer 270 may expose a part of the second reflective layer 250 to be electrically connected to the second electrode 280 formed thereafter.

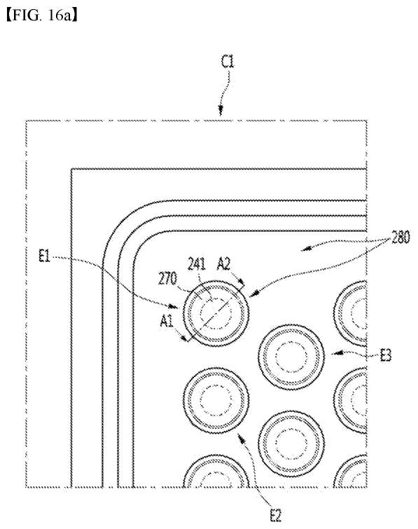

Next, FIG. 16A is an enlarged view of a first area portion C1 of the surface emitting laser device according to the embodiment, and FIG. 16B is a cross-sectional view taken along line A1-A2 of the surface emitting laser device according to the embodiment shown in FIG. 16A.

According to an embodiment, the contact electrode 282 may be formed on the second reflective layer 250, and a central region between the contact electrodes 282 may correspond to the aperture 241. The contact electrode 282 may improve ohmic contact characteristics with the second reflective layer 250. Rapid thermal annealing (RTP) may be performed to improve the ohmic contact characteristic between the contact electrode 282 and the second reflective layer 250.

Next, a pad electrode 284 in electrical contact with the contact electrode 282 may be formed, and the pad electrode 284 may be extended and disposed above the passivation layer 270 to receive current from the outside.

The contact electrode 282 and the pad electrode 284 may be made of a conductive material. For example, the contact electrode 282 and the pad electrode 284 include at least one of aluminum (Al), titanium (Ti), chromium (Cr), nickel (Ni), copper (Cu), and gold (Au). Thus, it can be formed in a single-layer or multi-layer structure.

Next, a first electrode 215 may be disposed under the substrate 210. Before the first electrode 215 is disposed, a part of the bottom surface of the substrate 210 may be removed through a predetermined grinding process, so that heat dissipation efficiency may be improved. The first electrode 215 may be made of a conductive material, for example, a metal. For example, the first electrode 215 includes at least one of aluminum (Al), titanium (Ti), chromium (Cr), nickel (Ni), copper (Cu), and gold (Au) and it can be formed into a structure.

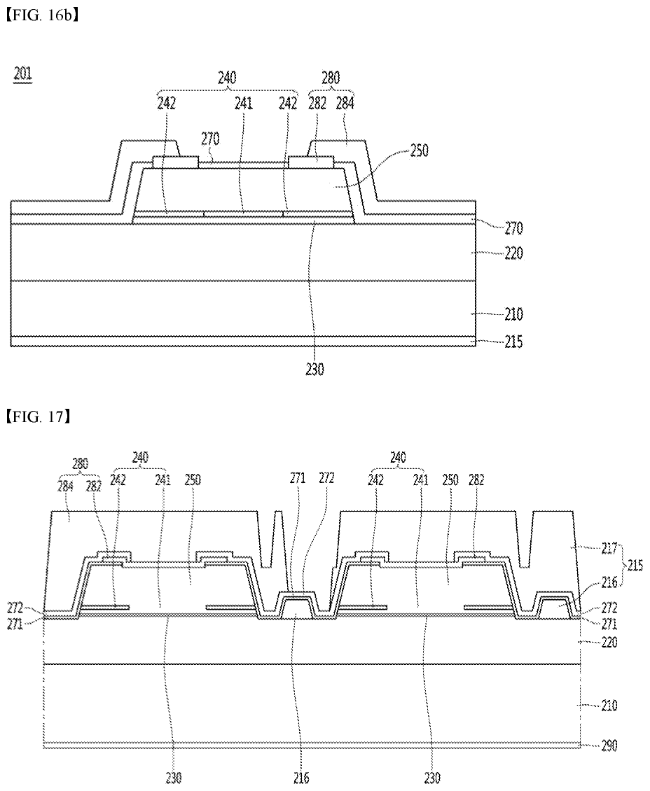

FIG. 17 is another cross-sectional view of a surface emitting laser device according to an embodiment.

In addition to the vertical type, the surface emitting laser device according to the embodiment may have a flip chip type in which the first electrode 215 and the second electrode 280 have the same direction as shown in FIG. 17.

For example, as shown in FIG. 17, the surface emitting laser device according to another embodiment includes a first electrode 215, a substrate 210, a first reflective layer 220, an active region 230, an aperture region 240, a second reflective layer 250, a second electrode 280, a first passivation layer 271, a second passivation layer 272, and a non-reflective layer 290. In this case, the reflectivity of the second reflective layer 250 may be designed to be higher than that of the first reflective layer 220.

In this case, the first electrode 215 may include a first contact electrode 216 and a first pad electrode 217 on the first reflective layer 220 exposed through a predetermined mesa process. The first contact electrode 216 may be electrically connected, and the first pad electrode 217 may be electrically connected to the first contact electrode 216.

The first electrode 215 may be made of a conductive material, for example, a metal. For example, the first electrode 215 includes at least one of aluminum (Al), titanium (Ti), chromium (Cr), nickel (Ni), copper (Cu), and gold (Au) and it can be formed into a structure.

When the first reflective layer 220 is an n-type reflective layer, the first electrode 215 may be an electrode for the n-type reflective layer.

Next, the second electrode 280 may include a second contact electrode 282 and a second pad electrode 284, and the second contact electrode 282 is electrically connected to the second reflective layer 250 Then, the second pad electrode 284 may be electrically connected to the second contact electrode 282.

When the second reflective layer 250 is a p-type reflective layer, the second electrode 280 may be an electrode for the p-type reflective layer.

The first insulating layer 271 and the second insulating layer 272 may be made of an insulating material, for example, nitride or oxide, for example, polyimide, silica (SiO₂). Or it may include at least one of silicon nitride (Si₃N₄).

The embodiment may provide a surface emitting laser device capable of improving electrical characteristics and a light emitting device including the same.

In addition, the embodiment can provide a surface emitting laser device capable of improving light output while improving voltage efficiency and a light emitting device including the same.

### First Additional Embodiment

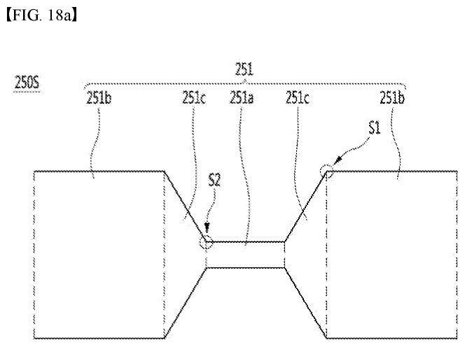

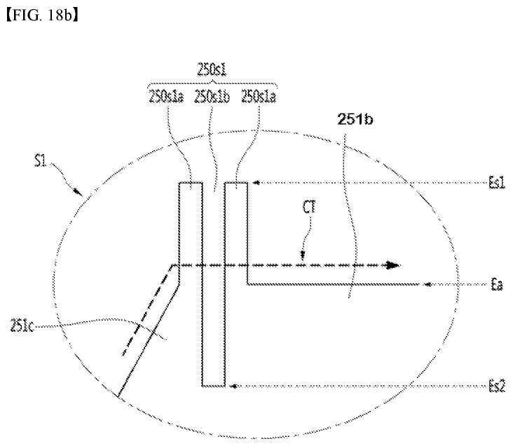

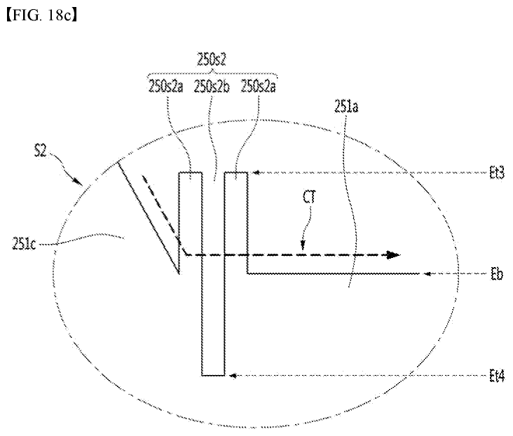

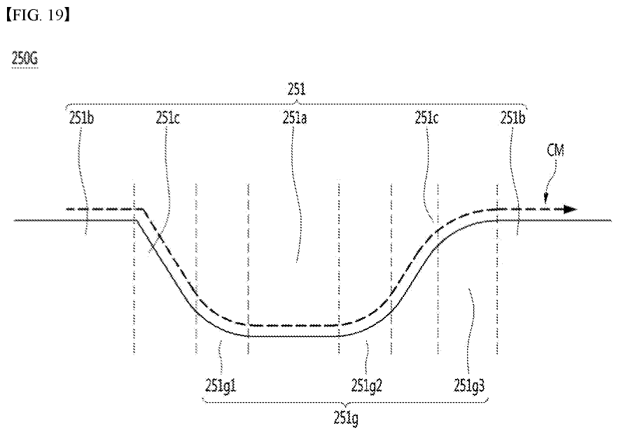

Hereinafter, a first additional embodiment will be described with reference to FIGS. 18A to 19.

One of the technical problems of the embodiment is to provide a surface emitting laser device capable of improving electrical characteristics and a light emitting device including the same.

In order to solve the above technical problem, the embodiment may provide a surface emitting laser device capable of improving electrical characteristics by improving resistance characteristics in a boundary region of a reflective layer, and a light emitting device including the same.

For example, FIG. 18A is another first energy band diagram for the first region 250S of the second reflective layer of the surface emitting laser device according to the embodiment illustrated in FIG. 4.

FIG. 18B is a first application example (Si) of the first region 250S of the second reflective layer of the surface emitting laser device according to the embodiment shown in FIG. 18A, and FIG. 18C is a surface according to the embodiment shown in FIG. 18A. This is a second application example (S2) of the first region 250S of the second reflective layer of the light emitting laser device.

The following description will be described centering on the second reflective layer 250, but the technical features of the embodiment may be applied to the first reflective layer 220 as well.

First, referring to FIG. 18A, the first group second reflective layer 251 of the embodiment may include a plurality of layers. For example, the first group second reflective layer 251 of the embodiment includes a second-first reflective layer 251a, a second-second reflective layer 251b, and a second-third reflective layer 251c there between.

According to the embodiment, an interface between adjacent reflective layers is provided by providing a second-third reflective layer 251c having an aluminum concentration in an intermediate region between the adjacent second-first reflective layer 251a and the second-second reflective layer 251b. There is a technical effect that can improve light output by reducing a carrier barrier by minimizing the generation of an electric field due to energy band bending in.

For example, when the first group second reflective layer 251 includes AlₓGa₍₁₋ₓ₎As (0<x<1), the second-first reflective layer 251b may be Al_{0.88}Ga_{0.12}As, the second-second reflective layer 251a may be Al_{0.12}Ga_{0.88}As, and the second-third reflective layer 251c may be Alₓ₃Ga₍₁₋ₓ₃₎As (0.12<X3<0.88), but is not limited thereto.

Through this, according to the embodiment, the interface between adjacent reflective layers is provided by providing the second-third reflective layer 251c having an aluminum concentration in the intermediate region between the adjacent second-first reflective layer 251b and the second-second reflective layer 251a. There is a technical effect of improving light output by lowering a carrier barrier by minimizing the generation of an electric field due to energy band bending at interface.

Accordingly, according to the embodiment, it is possible to provide a surface emitting laser device capable of improving light output by minimizing the influence of a carrier barrier due to generation of an electric field in a reflective layer, and a light emitting device including the same.

As described above, one of the technical problems of the embodiment is to provide a surface emitting laser device capable of improving electrical characteristics and a light emitting device including the same.

FIG. 18B is a first application example (Si) of the first region 250S of the second reflective layer of the surface emitting laser device according to the embodiment shown in FIG. 18A, and FIG. 18C is a surface according to the embodiment shown in FIG. 18A. This is a second application example (S2) of the first region 250S of the second reflective layer of the light emitting laser device.

Referring to FIG. 18B, the second reflective layer 250 according to the embodiment includes a first superlattice tunneling layer 250s1 between the second-third reflective layer 251c and the second-first reflective layer 251b. There is a special technical effect of reducing the resistance within the DBR and preventing an increase in the driving voltage by smoothing the carrier movement by the tunneling (CT) effect.

For example, the first superlattice tunneling layer 250s1 has a first energy level (Es′) of the first-first tunneling layer (250s1a) and a second energy level (Es2) of the first-second tunneling layer (250s1b) lower than the first energy level (Es1). The first energy level (Es′) of the first-first tunneling layer (250s1a) may be higher than the energy level (Ea) of the second-first reflective layer (251b). In addition, the second energy level Es2 of the first-second the tunneling layer 250s1b may be lower than the energy level Ea of the second-first reflective layer 251b.

In addition, the first energy level Es1 of the first superlattice tunneling layer 250s1 may be about 0.4 eV or more higher than the second energy level Es2 of the second superlattice tunneling layer 250s2, and each of the first superlattice tunneling layer 250s1 and the second superlattice tunneling layer 250s2 has a thickness of about 1 nm to 2 nm, thereby forming a superlattice structure and generating a carrier tunneling effect.

In an embodiment, the second-first reflective layer 251b may be Al_{0.88}Ga_{0.12}As, the second-second reflective layer 251a may be Al_{0.12}Ga_{0.88}As, and the second-third reflective layer 251c may be Alₓ₃Ga₍₁₋ₓ₃₎As (0.12<X3<0.88), the first-first tunneling layer 250s1a may be an AlAs layer, and the first-second tunneling layer 250s1b may be Alₓ₄Ga₁₋ₓ₄As (0.12<X4<0.88) may be used. For example, the first-second tunneling layer 250s1b may be Al_{0.45}Ga_{0.55}As, but is not limited thereto.

Next, FIG. 18C is a second application example S2 of the first region 250S of the second reflective layer of the surface emitting laser device according to the embodiment shown in FIG. 18A.

Referring to FIG. 18C, the second reflective layer 250 according to the embodiment includes a second superlattice tunneling layer 250s2 between the second-third reflective layer 251c and the second-second reflective layer 251a. There is a special technical effect of reducing the resistance within the DBR and preventing an increase in driving voltage by facilitating carrier movement by the tunneling (CT) effect.

For example, the second superlattice tunneling layer 250s2 includes a first-third tunneling layer (250s2a) of the third energy level (Et3) and a first-fourth tunneling layer (250s2b) of the fourth energy level (Et4) lower than the third energy level (Et3). The third energy level Et3 of the first-third tunneling layer 250s2a may be higher than the energy level Eb of the second-second reflective layer 251a. In addition, the fourth energy level Et4 of the first-fourth tunneling layer 250s2b may be lower than the energy level Eb of the second-second reflective layer 251a.

In addition, the third energy level Et3 of the third superlattice tunneling layer 250s2a may be about 0.4 eV or more higher than the fourth energy level Et4 of the fourth superlattice tunneling layer 250s2b. Each of the 3 superlattice tunneling layer 250s2a and the fourth superlattice tunneling layer 250s2b is formed to have a thickness of about 1 nm to 2 nm, thereby forming a superlattice structure and simultaneously generating a carrier tunneling effect.

In an embodiment, the second-first reflective layer 251b may be Al_{0.88}Ga_{0.12}As, the second-second reflective layer 251a may be Al_{0.12}Ga_{0.88}As, and the second-third reflective layer 251c may be Alₓ₃Ga₍₁₋ₓ₃₎As (0.12<X3<0.88).

In this case, the first-fourth tunneling layer 250s2b may be a GaAs layer, and the first-third tunneling layer 250s2a may be Alₓ₅Ga₁₋ₓ₄As (0.12<X5<0.88). For example the first-third tunneling layer 250s2a may be Al_{0.55}Ga_{0.45}As, but is not limited thereto.

According to an embodiment, the first superlattice tunneling layer 250s1 can be disposed between the second-first reflective layer 251b and the second-third reflective layer 251c or the second superlattice tunneling layer 250s2 can be disposed between the second-third reflective layer 251c and the second-first reflective layer 251a, such that there is a special technical effect of facilitating carrier movement by a carrier tunneling (CT) effect, thereby reducing resistance within the DBR and preventing an increase in driving voltage.

Next, FIG. 19 is a second energy band diagram 250G for a first region of the second reflective layer of the surface emitting laser device according to the embodiment illustrated in FIG. 4.

Referring to FIG. 19, a second reflective layer 250 according to an exemplary embodiment includes a graded reflective layer (251g) formed between the second-second reflective layer 251a and the second-third reflective layer 251c or between the second-first reflective layer 251b and the second reflective layer 251b. So a rounding area of bandgap energy is provided at the boundary between each reflective layer, thereby minimizing the band tail phenomenon to facilitate carrier movement (CM) and there is a technical effect of preventing a decrease in resistance and an increase in driving voltage.

For example, referring to FIG. 19, the second reflective layer 250 of the embodiment may include a first grading reflective layer 251g1 between the second-third reflective layer 251c and the second-second reflective layer 251a.

In an embodiment, the second-first reflective layer 251b may be Al_{0.88}Ga_{0.12}As, the second-second reflective layer 251a may be Al_{0.12}Ga_{0.88}As, and the second-third reflective layer 251c may be Alₓ₃Ga₍₁₋ₓ₃₎As (0.12<X3<0.88).

At this time, the first graded reflective layer 251g1 may include a composition of Al_{g1}Ga_{(1-g1)}As (0.12<g1<X3), and the composition of the first Al of the first graded reflective layer 251g1 (g1) may decrease along a curved slope from the second-third reflective layer 251c toward the second-second reflective layer 251a.

Further, referring to FIG. 19, the second reflective layer 250 of the embodiment may include a second grading reflective layer 251g2 between the second-second reflective layer 251a and the second-third reflective layer 251c.

At this time, the second graded reflective layer 251g2 may include a composition of Al_{g2}Ga_{(1-g2)}As (0.12<g2<X3), and the second Al composition of the second graded reflective layer 251g2 (g2) may increase along a curve slope from the second-second reflective layer 251a toward the second-third reflective layer 251c.

Further, referring to FIG. 19, the second reflective layer 250 of the embodiment may include a third grading reflective layer 251g3 between the second-third reflective layer 251c and the second-first reflective layer 251b.

At this time, the third graded reflective layer 251g3 may include a composition of Al_{g3}Ga_{(1-g3)}As(X3<g3<0.88), and the third Al composition of the third graded reflective layer 251g3 (g3) may increase along a curve slope from the second-third reflective layer 251c toward the second-first reflective layer 25 lb.

Accordingly, according to an embodiment, the second reflective layer 250 includes the graded reflective layer (251g) provided between the second-second reflective layer 251a and the second-third reflective layer 251c or between the second-first reflective layer 251b and the second-third the reflective layers (251c). So a rounding region of bandgap energy is provided at the boundary between each reflective layer, thereby minimizing the band tail phenomenon, thereby facilitating carrier movement (CM) within the reflective layer such that there is a technical effect of reducing resistance and preventing an increase in driving voltage.

### Second Additional Embodiment

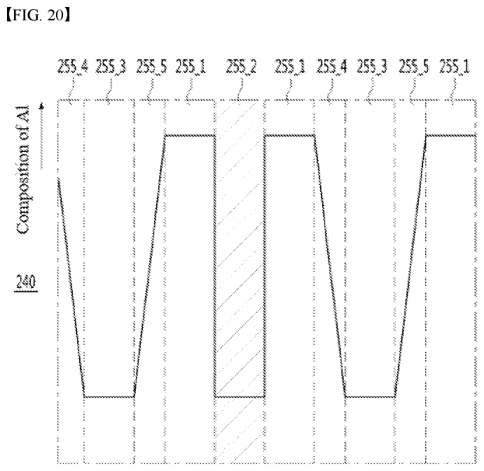

FIG. 20 is data on the Al concentration distribution in the second reflective layer of the surface emitting laser device according to the second additional embodiment.

In the surface emitting laser device 201 according to the second additional embodiment, the remaining components except for the first group second reflective layer 251 of the second reflective layer 250 are the same as the surface emitting laser device according to the above-described embodiment. These remaining components can be easily understood from the first and second embodiments. Hereinafter, a description will be made focusing on the second reflective layer 250.

In an embodiment, the second reflective layer 250 may include a first group second reflective layer 251 and a second group second reflective layer 252. The first group second reflective layer 251 and the second group second reflective layer 252 may include a second conductivity type dopant, such as a p type dopant. Examples of P-type dopants include Mg, Zn, Ca, Sr, and Ba.

For example, the first group second reflective layer 251 and the second group second reflective layer 252 may include AlₓGa₍₁₋ₓ₎As (0<x<1).

As shown in FIG. 20, the first group second reflective layer 251 may include a plurality of reflective layers 255_1 to 255_5.

According to a second additional embodiment, one reflective layer 255_2 of the plurality of reflective layers 255_1 to 255_5 has a second carrier, such as a hole, in the plane direction of the reflective layer 255_2, that is, in the in plane direction. It may be a current diffusion layer that guides the diffusion. Since the moving direction of the hole by the reflective layer 255_2 means the flow of current, the current density phenomenon in which the current flowing from the second reflective layer 250 to the light emitting layer 230 is concentrated along the edge of the aperture region 241 such that it is alleviated or can be removed, the divergence angle of the beam of the light emitting layer 230 does not change, so that reliability and quality of the product may be improved.

According to a second additional embodiment, the first group second reflective layer 251 may include a plurality of first-first reflective layers 255_1. The first-first reflective layer 255_1 may include a gallium-based compound, for example, AlGaAs, but is not limited thereto.

The first-first reflective layer 255_1 may have a first aluminum concentration. The first-first reflective layer 255_1 may include Al_{0.88}Ga_{0.12}As. That is, the first aluminum concentration may be 0.88.

According to a second additional embodiment, the first group second reflective layer 251 may include at least one first-second reflective layer 255_2. At least one first-second reflective layer 255_2 may be disposed between adjacent first-first reflective layers 255_1. The first-second reflective layer 255_2 may include a gallium-based compound, for example, AlGaAs, but is not limited thereto.

The first-second reflective layer 255_2 may have a second aluminum concentration. The second aluminum concentration may be lower than the first aluminum concentration.

The first-second reflective layer 255_2 will be described in more detail later.

According to a second additional embodiment, the first group second reflective layers 251 may include a plurality of first-third reflective layers 255_3. The first-third reflective layers 255_3 may be disposed between adjacent first-first reflective layers 255_1. The third reflective layer 255_2 may include a gallium-based compound, for example, AlGaAs, but is not limited thereto.

The first-third reflective layer 255_3 may have a third aluminum concentration. The third aluminum concentration may be lower than the first aluminum concentration. The third aluminum concentration may be equal to or higher than the second aluminum concentration. The first-third reflective layer 255_3 may include Al_{0.12}Ga_{0.88}As. In this case, the second aluminum concentration may be 0.12 or lower.

According to a second additional embodiment, the first group of second reflective layers 251 may include first-fourth reflective layers 255_4. The first-fourth reflective layer 255_4 may be disposed between the first-first reflective layer 255_1 and the first-third reflective layer 255_3.

The first-fourth reflective layers 255_4 may have a fourth aluminum concentration. The fourth aluminum concentration may be graded or varied. For example, the fourth aluminum concentration may be grayed so as to decrease from the first aluminum concentration to the third aluminum concentration from the first-first reflective layer 255_1 to the third-third reflective layer 255_3. That is, the fourth aluminum concentration at one end of the first-first reflective layer 255_4 contacting the first-first reflective layer 255_1 may be the same as the first aluminum concentration of the first-first reflective layer 255_1. The fourth aluminum concentration at the other end of the first-fourth reflective layer 255_4 in contact with the first-third reflective layer 255_3 may be the same as the third aluminum concentration of the first-third reflective layer 255_3.

The first-fourth reflective layers 255_4 may include Alₓ₃Ga₍₁₋ₓ₃₎As (0.12<X3<0.88).

According to a second additional embodiment, the first group of second reflective layers 251 may include the first-fifth reflective layers 255_5. The first-fifth reflective layer 255_5 may be disposed between the first-first reflective layer 255_1 and the first-third reflective layer 255_3.

The first-fifth reflective layers 255_5 may have a fifth aluminum concentration. The fifth aluminum concentration can be graded or varied. For example, the fifth aluminum concentration may be grayed to decrease from the third aluminum concentration to the first aluminum concentration from the first-third reflective layer 255_3 to the first-first reflective layer 255_1. That is, the concentration of the fifth aluminum at one end of the first-fifth reflective layer 255_5 in contact with the first-third reflective layer 255_3 may be the same as the third aluminum concentration of the first-third reflective layer 255_3. The fifth aluminum concentration at the other end of the first-fifth reflective layer 255_5 in contact with the first-first reflective layer 255_1 may be the same as the first aluminum concentration of the first-first reflective layer 255_1.

The first-fifth reflective layer 255_5 may include Alₓ₄Ga₍₁₋ₓ₄₎As (0.12<X4<0.88), but is not limited thereto.

Hereinafter, the first-second reflective layer 255_2 will be described in more detail.

Each of the first-first reflective layer 255_1, the first-third reflective layer 255_3, the first-fourth reflective layer 255_4, and the first-fifth reflective layer 255_5 may include a second conductivity type dopant, such as a p-type dopant. Examples of P-type dopants include Mg, Zn, Ca, Sr, and Ba. The concentrations of the second conductivity type dopants included in each of the first-first reflective layer 255_1, the first-third reflective layer 255_3, the first-fourth reflective layer 255_4, and the first-fifth reflective layer 255_5 may be different.

Meanwhile, the first-second reflective layer 255_2 may not include a second conductivity type dopant. That is, the doping concentration of the first-second reflective layer 255_2 may be zero. Since the first-second reflective layer 255_2 does not contain the second conductivity-type dopant, the resistance of the first-second reflective layer 255_2 increases, so that the holes generated in the second reflective layer 250 are formed in the first-second reflective layer 255_2 and can be diffused in the transverse direction. Accordingly, the intensity or amount of current flowing from the second reflective layer 250 to the light emitting layer 240 is reduced, thereby reducing the current concentration phenomenon in which the current in the second reflective layer 250 is concentrated along the edge of the aperture region 241. Since the current concentration phenomenon can be removed or removed, the divergence angle of the beam of the light emitting layer 230 does not change, so that reliability and quality of the product may be improved.

As another example, the first-second reflective layer 255_2 includes a second conductivity type dopant, but may be lower than the concentration of the second conductivity type dopant of the first-third reflective layer 255_3. For example, the concentration of the second conductivity type dopant in the first-second reflective layer 255_2 may be 1E17/cm³ to 1E19/cm³. For example, the concentration of the second conductivity type dopant in the first-second reflective layer 255_2 may be 5E 17/cm³ or less. For example, the concentration of the second conductivity type dopant in the first-second reflective layer 255_2 may be 1E15/cm³ to 1E17/cm³. In this case, the second conductivity type dopant may be doped up to 95% of the total thickness of the first-second reflective layer 255_2, and the doping level may be varied in the first-second reflective layer 255_2.

As another example, the first-second reflective layer 255_2 may include a first conductivity type dopant. For example, the first conductivity-type dopant may include an n-type dopant such as Si, Ge, Sn, Se, and Te. Since the first-second reflective layer 255_2 is doped with a first conductivity type dopant having a polarity opposite to that of the second conductivity type dopant, the resistance of the first-second reflective layer 255_2 is further increased, and thus current flows in a transverse direction rather than in a vertical direction, so that the current congestion phenomenon that is concentrated along the edge of the aperture region 241 is alleviated or eliminated and quality can be improved.

A first-fourth reflective layer 255_4 and a first-fifth reflective layer 255_5 may be disposed on both sides of the first-third reflective layer 255_3. For example, a first-fourth reflective layer 255_4 may be in contact with one side of the first-third reflective layer 255_3, and a first-fifth reflective layer 255_5 may be disposed on the other side of the first-third reflective layer 255_3.

The first-fourth reflective layer 255_4 and the first-fifth reflective layer 255_5 may not be disposed on both sides of the first-second reflective layer 255_2. That is, the first-first reflective layer 255_1 may be directly disposed on both sides of the first-second reflective layer 255_2. For example, one of the first-first reflective layers 255_1 adjacent to the first-first reflective layer 255_1 is in contact with one side of the first-second reflective layer 255_2, and the other of the adjacent first-first reflective layers 255_1 may contact the other side of the first-second reflective layer 255_2.

Since the first-first reflective layers 255-1 are in contact with adjacent both sides of the first-second reflective layer 255_2, aluminum concentration at first interface between the first-second reflective layer 255_2 and one of the first-first reflective layers 255_1 or at second interface between the first-second reflective layer 255_2 and the other of the first-first reflective layers 255_1 may rapidly fluctuate.

For example, from the first aluminum concentration of one of the first-first reflective layers 255_1 adjacent to the aluminum concentration at the first interface to the second aluminum concentration of the first-second reflective layer 255_2 can be abruptly lowered or reduced.

For example, the aluminum concentration at the second interface is from the second aluminum concentration of the first-second reflective layer 255_2 to the first aluminum concentration of one of the first-first reflective layers 255_1 adjacent to the first-first reflective layer 255_1 can be rapidly elevated or increased.

In other words, the aluminum concentration at the first interface and/or the second interface may not be graded, and may jump or transition from the second aluminum concentration to the first aluminum concentration or from the first aluminum concentration to the second aluminum concentration.

The aluminum concentration is proportional to the energy band gap. Accordingly, when the aluminum concentration is increased, the energy band gap may increase, and when the aluminum concentration is decreased, the energy band gap may decrease. The energy band gap at the first interface rapidly decreases, and the energy band gap at the second interface rapidly increases, so that holes in the second reflective layer 250 are trapped in the first-second reflective layers 255_2 as much as possible. As a result, the current concentration phenomenon in which the current in the second reflective layer 250 is concentrated along the aperture edge may be alleviated or eliminated.

Since the aluminum concentration rapidly fluctuates in a region between the first-second reflective layer 255_2 and the adjacent first-first reflective layer 255_1, the first-second reflective layer 255_2 may have an abrupt type structure.

For example, in the aluminum concentration change, the thickness of a region in which the first aluminum concentration of the first-first reflective layer 255_1 changes to the second aluminum concentration of the first-second reflective layer 255_2 may be 5 nm or less. The first aluminum concentration of the first-first reflective layer 255_1 may be rapidly changed in the region of 5 nm or less by the second aluminum concentration of the first-second reflective layer 255_2. Preferably, the thickness of a region in which the first aluminum concentration of the first-first reflective layer 255_1 changes to the second aluminum concentration of the first-second reflective layer 255_2 may be 3 nm or less.

For example, in the aluminum concentration, the first level of the first-second reflective layer 255_2 may be changed to the second level of the adjacent first-first reflective layer 255-1. The first level of aluminum concentration may be maintained in the first-second reflective layer 255_2, and the second level higher than the first level may be maintained in the first-first reflective layer 255-1. Accordingly, at the interface between the first-second reflective layer 255_2 and the first-first reflective layer 255_1 adjacent to the first level, the aluminum concentration varies from the first level to the second level, or the second level of the aluminum concentration can fluctuate with levels of aluminum concentration.

In this way, as the concentration of the second conductivity type dopant in the first-second reflective layer 255_2 is lowered, the resistance of the first-second reflective layer 255_2 increases, so that the hole in the second reflective layer 250 becomes the first-second reflective layer. Since it diffuses in the transverse direction at first-second reflective layer 255_2, the current density phenomenon in which the current in the second reflective layer 250 is concentrated along the aperture edge is alleviated or eliminated, so the divergence angle of the beam of the light emitting layer 230 does not change, Reliability and quality can be improved. In addition, compared to the example in which the dopant is not included in the first-second reflective layer 255_2 in the above-described example, the dopant is included in the first-second reflective layer 255_2 and the resistance is relatively reduced or can be lowered.

The first-second reflective layer 255_2 may be disposed 10 nm to 100 nm apart from the oxide layer 240. When the first-second reflective layer 255_2 is disposed less than 10 nm apart, it is too close to the aperture region 241 of the oxide layer 240, and it is difficult to mitigate the current density phenomenon caused by the first-second reflective layer 255_2. When the first-second reflective layer 255_2 is disposed beyond 100 nm, the first-second reflective layer 255_2 is separated from the aperture region 241 of the oxide layer 240 and passes through the first-second reflective layer 255_2 Thus, current condensation may still occur due to the current flowing to the aperture region 241 of the oxide layer 240.

For example, the first-second reflective layer 255_2 may be spaced apart from the oxide layer 240 by 15 nm or more. For example, the first-second reflective layer 255_2 may be separated from the oxide layer 240 by 15 nm to 50 nm. For example, the first-second reflective layer 255_2 may be separated from the oxide layer 240 by 15 nm to 30 nm.

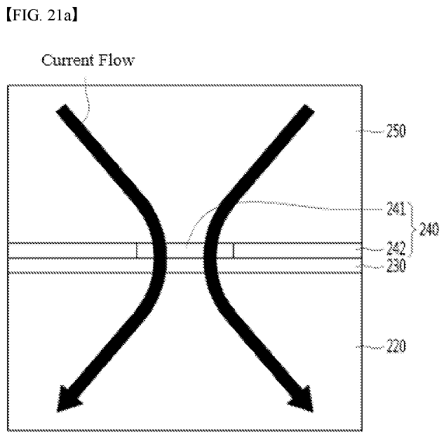

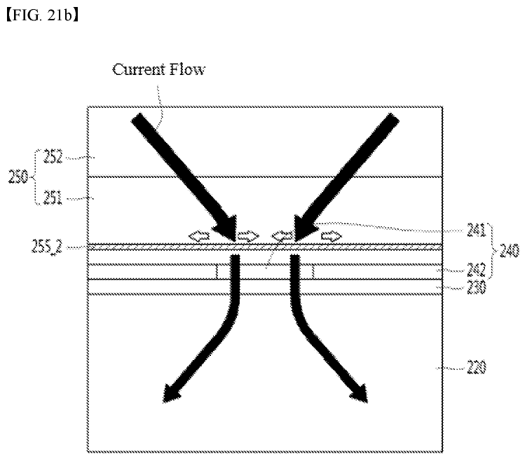

FIG. 21A shows a current density phenomenon in a conventional surface emitting laser device, and FIG. 21B shows a state in which current density in the surface emitting laser device 201 according to a second additional embodiment is alleviated.

As shown in FIG. 21A, in the conventional surface emitting laser device, current flows through the aperture region 241 that is smaller than the size of the light-emitting layer, resulting in a current concentration phenomenon in which the current is concentrated around the inside of the insulating area.

As shown in FIG. 21B, according to the second additional embodiment, the first-fourth reflective layer 255_4 and the first-fifth reflective layer 255_5 for which the aluminum concentration is graded on the second reflective layer 250 are omitted. The first-second reflective layer 255_2, which is in contact with the first-first reflective layer 255_1 and does not contain a relatively low doping concentration or dopant, is provided, so that some of the current flowing from the second reflective layer 250 to the light emitting layer 230 is transverse. The current concentration generated inside the insulating region 242 by spreading in the direction may be alleviated or eliminated. As the current density is reduced or eliminated in this way, the divergence angle of the beam of the light emitting layer 230 does not change, so that reliability and quality of the product may be improved.

According to a second additional embodiment, the first group of the second reflective layer 250 includes a second conductivity-type dopant having a relatively low energy band gap and a low doping concentration in the second reflective layer 251 or By including at least one second reflective layer 255_2 that includes a conductive dopant or does not contain a second conductive dopant, the resistance of the second reflective layer 255_2 increases, so that the hole in the second reflective layer 250 may diffuse in the plane direction of the second reflective layer 255_2. Accordingly, since the current density phenomenon in which the current in the second reflective layer 250 is concentrated along the aperture edge is alleviated or eliminated, the divergence angle of the beam of the light emitting layer 230 does not change, thereby improving the reliability and quality of the product.

According to the second additional embodiment, the aluminum concentration in the intermediate region between the adjacent first-third reflective layer 255_3 and the first-1 reflective layer 255_1 of the second reflective layer 250 on the emission layer 230, that is, by providing the first-fourth reflective layer 255_4 or the first-fifth reflective layer 255_5 having the fifth aluminum concentration, such that a generation of an electric field due to band bending is minimized at the interface between each layer (255p, 255q, 255r, 255s) of the second reflective layer 250, so that the carrier barrier is lowered, thereby improving light output.

Meanwhile, in the embodiment, the thickness of the first-first reflective layer 255_1 may be thicker than the thickness of the first-third reflective layer 255_3. In addition, the thickness of the first-third reflective layer 255_3 or the first-first reflective layer 255_1 may be thicker than the thickness of the first-fourth reflective layer 255_4 or the first-fifth reflective layer 255_5.

In this case, the first aluminum concentration of the first-first reflective layer 255_1 may be higher in the third aluminum concentration of the first-third reflective layer 255_3. In addition, the third aluminum concentration of the first-third reflective layers 255_3 may be higher than the fourth aluminum concentration of the first-fourth reflective layers 255_4 or the fifth aluminum concentration of the first-fifth reflective layers 255_5.

Accordingly, since the thickness of the first-first reflective layer 255_1, which has a relatively high aluminum concentration, is thicker than the thickness of the first-third reflective layer 255_3, the grating quality may be improved, thereby contributing to light output.

In addition, since the thickness of the first-third reflective layer 255_3 having a relatively high aluminum concentration is thicker than the thickness of the first-fourth reflective layer 255_4 or the first-fifth reflective layer 255_5, it is possible to contribute to light output by improving the lattice quality.

For example, the thickness of the first-first reflective layer 255_1 may be about 50 to 55 nm, the thickness of the first-third reflective layer 255_3 may be about 26 to 32 nm, and the first reflective layer having a relatively high aluminum concentration, and also the thickness of the first-first reflective layer 255_1 is thicker than the thickness of the first-third reflective layers 255_3, such that the grating quality may be improved, thereby contributing to light output.

In addition, the thickness of the first-fourth reflective layer 255_4 may be about 22 to 27 nm, the thickness of the first-fifth reflective layer 255_5 may be about 22 to 27 nm, and the aluminum concentration is relatively high. Since the thicknesses of the first-first reflective layer 255_1 and the first-third reflective layers 255_3 are thicker than those of the first-fourth reflective layers 255_4 and first-fifth reflective layers 255_5, the lattice quality may be improved to contribute to light output.

### Third Additional Embodiment

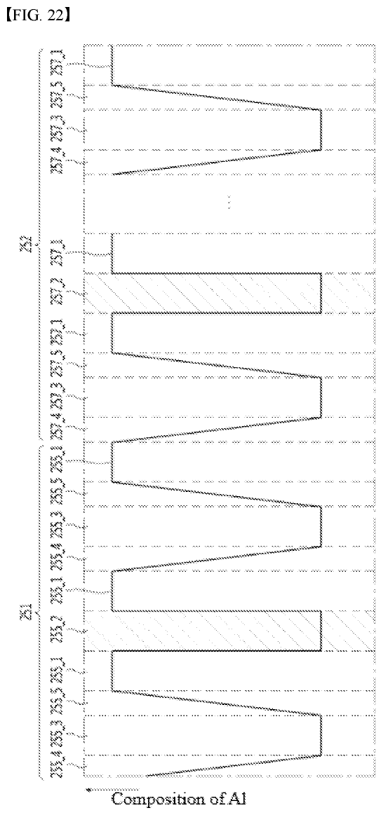

FIG. 22 is data on Al concentration distribution in the second reflective layer 250 of the surface emitting laser device according to the third additional embodiment.

In a third additional embodiment, a layer including a second conductivity type dopant having a relatively low energy band gap and also having a low doping concentration, or containing a first conductivity type dopant or no second conductivity type dopant is a second layer. It is the same as the second additional embodiment except that it is further included in the group second reflective layer 252. In the surface emitting laser device 201 according to the third additional embodiment, the remaining components except for the second reflective layer 250 are the same as those of the surface emitting laser device according to the first to second additional embodiments. Hereinafter, a description will be made focusing on the second reflective layer 250.

According to a third additional embodiment, the second reflective layer 250 includes a plurality of current diffusion layers, and an interval between adjacent current diffusion layers may be 50 nm or more. For example, the current diffusion layer may be the first-second reflective layers 255_2, 257_2 shown in FIG. 22.

In an embodiment, the second reflective layer 250 may include a first group second reflective layer 251 and a second group second reflective layer 252. The first group second reflective layer 251 and the second group second reflective layer 252 may include a second conductivity type dopant, such as a p type dopant. Examples of P-type dopants include Mg, Zn, Ca, Sr, and Ba.

For example, the first group second reflective layer 251 and the second group second reflective layer 252 may include AlₓGa₍₁₋ₓ₎As (0<x<1).

As shown in FIG. 22, the first group second reflective layer 251 may include a plurality of reflective layers 257_1 to 257_5.

According to a third additional embodiment, one reflective layer 257_2 among the plurality of reflective layers 257_1 to 257_5 guides a second carrier, such as a hole, to diffuse in the plane direction of the reflective layer 257_2, that is, in the transverse direction. Since the moving direction of the hole by the reflective layer 257_2 means the flow of current, the current dense phenomenon in which the current flowing from the second reflective layer 250 to the light emitting layer 230 is concentrated along the edge of the aperture region 241 is alleviated or can be removed, the divergence angle of the beam of the light emitting layer 230 does not change, so that reliability and quality of the product may be improved.

According to a third additional embodiment, the second group second reflective layer 252 may include a plurality of first-first reflective layers 257_1. The first-first reflective layer 257_1 may include a gallium-based compound, for example, AlGaAs, but is not limited thereto.

The first-first reflective layer 257_1 may have a first aluminum concentration. The first-first reflective layer 257_1 may include Al_{0.88}Ga_{0.12}As. That is, the first aluminum concentration may be 0.88.

According to a third additional embodiment, the second group second reflective layer 252 may include at least one first-second reflective layer 257_2. At least one first-second reflective layer 257_2 may be disposed between adjacent first-first reflective layers 257_1. The first-second reflective layer 257_2 may include a gallium-based compound, for example, AlGaAs, but is not limited thereto.

The first-second reflective layer 257_2 may have a second aluminum concentration. The second aluminum concentration may be lower than the first aluminum concentration.

The first-second reflective layer 257_2 will be described in more detail later.

According to a third additional embodiment, the second group second reflective layer 252 may include a plurality of first-third reflective layers 257_3. The first-third reflective layer 257_3 may be disposed between adjacent first-first reflective layers 257_1. The third reflective layer 257_2 may include a gallium-based compound, for example, AlGaAs, but is not limited thereto.

The first-third reflective layers 257_3 may have a third aluminum concentration. The third aluminum concentration may be lower than the first aluminum concentration. The third aluminum concentration may be equal to or higher than the second aluminum concentration. The first-third reflective layer 257_3 may include Al_{0.12}Ga_{0.88}As. In this case, the second aluminum concentration may be 0.12 or lower.

According to a third additional embodiment, the second group second reflective layer 252 may include first-fourth reflective layers 257_4. The first-fourth reflective layer 257_4 may be disposed between the first-first reflective layer 257_1 and the first-third reflective layer 257_3.

The first-fourth reflective layers 257_4 may have a fourth aluminum concentration. The fourth aluminum concentration can be graded or varied. For example, the fourth aluminum concentration may be grayed to decrease from the first aluminum concentration to the third aluminum concentration from the first-first reflective layer 257_1 to the first-third reflective layer 257_3. That is, the fourth aluminum concentration at one end of the first-first reflective layer 257_4 in contact with the first-first reflective layer 257_1 may be the same as the first aluminum concentration of the first-first reflective layer 257_1. The fourth aluminum concentration at the other end of the first-fourth reflective layer 257_4 in contact with the first-third reflective layer 257_3 may be the same as the third aluminum concentration of the first-third reflective layer 257_3.

The first-fourth reflective layers 257_4 may include Alₓ₃Ga₍₁₋ₓ₃₎As (0.12<X3<0.88).

According to a third additional embodiment, the second group second reflective layer 252 may include the first-fifth reflective layers 257_5. The first-fifth reflective layer 257_5 may be disposed between the first-first reflective layer 257_1 and the first-third reflective layer 257_3.

The first-fifth reflective layers 257_5 may have a fifth aluminum concentration. The fifth aluminum concentration can be graded or varied. For example, the fifth aluminum concentration may be grayed to decrease from the third aluminum concentration to the first aluminum concentration from the first-third reflective layer 257_3 to the first-first reflective layer 257_1. That is, the concentration of the fifth aluminum at one end of the first-fifth reflective layer 257_5 in contact with the first-third reflective layer 257_3 may be the same as the third aluminum concentration of the first-third reflective layer 257_3. The fifth aluminum concentration at the other end of the first-fifth reflective layer 257_5 in contact with the first-first reflective layer 257_1 may be the same as the first aluminum concentration of the first-first reflective layer 257_1.

The first-fifth reflective layer 257_5 may include Alₓ₄Ga₍₁₋ₓ₄₎As (0.12<X4<0.88), but is not limited thereto.

Hereinafter, the first-second reflective layer 257_2 will be described in more detail.

Each of the first-first reflective layer 257_1, the first-third reflective layer 257_3, the first-fourth reflective layer 257_4 and the first-fifth reflective layer 257_5 may include a second conductivity type dopant, for example a p-type dopant. Examples of P-type dopants include Mg, Zn, Ca, Sr, and Ba. The concentration of the second conductivity type dopant included in each of the first-first reflective layer 257_1, the first-third reflective layer 257_3, the first-fourth reflective layer 257_4, and the first-fifth reflective layer 257_5 may be different.

Meanwhile, the first-second reflective layer 257_2 may not include a second conductivity type dopant. Since the second conductivity type dopant is not included in the first-second reflective layer 257_2, the resistance of the first-second reflective layer 257_2 increases, so that the holes generated in the second reflective layer 250 are formed in the first-second reflective layer 257_2 can be diffused in the transverse direction. Accordingly, the intensity or amount of current flowing from the second reflective layer 250 to the light emitting layer 240 is reduced, thereby reducing the current concentration phenomenon in which the current in the second reflective layer 250 is concentrated along the edge of the aperture region 241. Since it can be removed, the divergence angle of the beam of the light emitting layer 230 does not change, so that reliability and quality of the product may be improved.

As another example, the first-second reflective layer 257_2 includes a second conductivity type dopant, but may be lower than the concentration of the second conductivity type dopant of the first-third reflective layer 257_3. For example, the concentration of the second conductivity type dopant in the first-second reflective layer 257_2 may be 1E 17/cm³ to 1E 19/cm³. At this time, the second conductivity type dopant may be doped up to 95% of the total thickness of the first-second reflective layer 257_2, and its doping level may be varied within the first-second reflective layer 257_2.

As another example, the first-second reflective layer 257_2 may include a first conductivity type dopant. For example, the first conductivity-type dopant may include an n-type dopant such as Si, Ge, Sn, Se, and Te. Since the first-second reflective layer 257_2 is doped with a first conductivity type dopant having a polarity opposite to that of the second conductivity type dopant, the resistance of the first-second reflective layer 257_2 is further increased, and current flows in a transverse direction rather than in a vertical direction, thereby reducing or eliminating the current congestion phenomenon that is concentrated along the edge of the aperture region 241, so the divergence angle of the beam of the light-emitting layer 230 does not change, so the reliability of the product and quality can be improved.

A first-fourth reflective layer 257_4 and a first-fifth reflective layer 257_5 may be disposed on both sides of the first-third reflective layer 257_3. For example, a first-fourth reflective layer 257_4 may be in contact with one side of the first-third reflective layer 257_3, and a first-fifth reflective layer 257_5 may be disposed on the other side of the first-third reflective layer 257_3.

The first-fourth reflective layers 257_4 and first-fifth reflective layers 257_5 may not be disposed on both sides of the first-second reflective layer 257_2. That is, the first-first reflective layer 257_1 may be directly disposed on both sides of the first-second reflective layer 257_2. For example, one of the first-first reflective layers 257_1 is in contact with one side of the first-second reflective layer 257_2, and the other of the adjacent first-first reflective layers 257_1 may contact the other side of the first-second reflective layer 257_2.

Since the first-first reflective layers 257-1 adjacent to both sides of the first-second reflective layer 257_2 come into contact, the aluminum concentration at a first interface between one of the first-first reflective layers 257_1 and one side of the first-second reflective layer 257_2 or at a second interface between the first-first reflective layer 257_1 and the other side of the first-second reflective layer 257_2 may rapidly fluctuate.

For example, from the first aluminum concentration of one of the first-first reflective layers 257_1 adjacent to the first-first reflective layer 257_1 at the first interface to the second aluminum concentration of the first-second reflective layer 257_2 can be rapidly lowered or decreased.

For example, the aluminum concentration at the second interface is from the second aluminum concentration of the first-second reflective layer 257_2 to the first aluminum concentration of one of the first-first reflective layers 257_1 adjacent to the first-first reflective layer 257_1 can be rapidly elevated or increased.

In other words, the aluminum concentration at the first interface and/or the second interface is not graded and may jump or transition from the second aluminum concentration to the first aluminum concentration or from the first aluminum concentration to the second aluminum concentration.

The aluminum concentration is proportional to the energy band gap. Accordingly, when the aluminum concentration is increased, the energy band gap may increase, and when the aluminum concentration is decreased, the energy band gap may decrease. The energy band gap at the first interface rapidly decreases, and the energy band gap at the second interface rapidly increases, so that holes in the second reflective layer 250 are trapped in the first-second reflective layer 257_2 as much as possible. As a result, the current concentration phenomenon in which the current in the second reflective layer 250 is concentrated along the aperture edge may be alleviated or eliminated.

In this way, as the concentration of the second conductivity type dopant in the first-second reflective layer 257_2 decreases, the resistance of the first-second reflective layer 257_2 increases, so that the hole in the second reflective layer 250 diffuses in the transverse direction at first-second reflective layer 257_2, the current density phenomenon in which the current in the second reflective layer 250 is concentrated along the aperture edge is alleviated or eliminated, so the divergence angle of the beam of the light emitting layer 230 does not change and reliability and quality can be improved. In addition, compared to the example in which the dopant is not included in the first-second reflective layer 257_2 in the above-described example, since the dopant is included in the first-second reflective layer 257_2, the resistance is relatively reduced or can be lowered.

The second-second reflective layer 257_2 may be disposed 200 nm to 300 nm apart from the oxide layer 240. When the second-second reflective layer 257_2 is disposed exceeding 200 nm, the second-second reflective layer 257_2 is too far away from the aperture region 241 of the oxide layer 240 and passes through the second-second reflective layer 257_2 Thus, current condensation may still occur due to the current flowing to the aperture region 241 of the oxide layer 240.

For example, the second-second reflective layer 257_2 may be spaced apart from the oxide layer 240 by 200 nm to 230 nm.

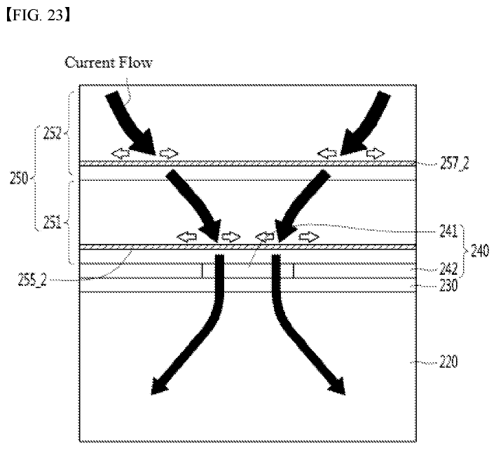

FIG. 23 shows the degree of current density according to the third additional embodiment.

As shown in FIG. 23, according to the third additional embodiment, the second-fourth reflective layer 257_4 and the second-fifth reflective layer 257_5 for which aluminum concentration is graded on the second reflective layer 250 are omitted. The second-second reflective layer 257_2 that contacts the second-first reflective layer 257_1 does not contain a relatively low doping concentration or dopant is provided, so that some of the current flowing from the second reflective layer 250 to the emission layer 230 is in the disrobed direction. The current concentration generated inside the insulating region 242 may be reduced or eliminated by diffusion. As the current density is reduced or eliminated in this way, the divergence angle of the beam of the light emitting layer 230 does not change, so that reliability and quality of the product may be improved.

According to a third additional embodiment, the second reflective layer 250 includes a second conductivity type dopant having a relatively low energy band gap and a low doping concentration, a first conductivity type dopant, or a second conductivity type. At least one or more second reflective layers 257_1,257_2 that do not contain a dopant are included in the second group second reflective layer 252 as well as the first group second reflective layer 251, so that resistance of the first group second reflective layer 251 is increased in each of the corresponding second reflective layer 257_1 and the second reflective layer 257_2 of the second group second reflective layer 252 so that the holes in the second reflective layer 250 can diffuse in each plane direction. Accordingly, since the current density phenomenon in which the current in the second reflective layer 250 is concentrated along the aperture edge is more reliably alleviated or eliminated, the divergence angle of the beam of the light-emitting layer 230 does not change, so the reliability and quality of the product.

(Mobile Terminal)

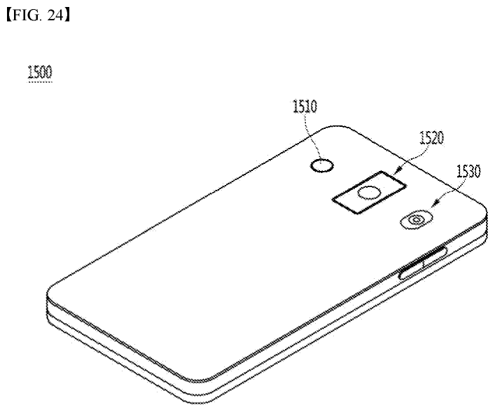

Next, FIG. 24 is a perspective view of a mobile terminal to which a surface emitting laser device is applied according to an embodiment.

As shown in FIG. 24, the mobile terminal 1500 according to the embodiment may include a camera module 1520, a flash module 1530, and an autofocus device 1510 provided on the rear side. Here, the autofocus device 1510 may include one of the packages of the surface emitting laser device according to the above-described embodiment as a light emitting unit.

The flash module 1530 may include a light emitting device that emits light therein. The flash module 1530 may be operated by a camera operation of a mobile terminal or a user's control.

The camera module 1520 may include an image capturing function and an auto focus function. For example, the camera module 1520 may include an auto focus function using an image.

The auto focus device 1510 may include an auto focus function using a laser. The auto focus device 1510 may be mainly used in a condition in which an auto focus function using an image of the camera module 1520 is deteriorated, for example, in a proximity or dark environment of 10 m or less. The auto-focusing device 1510 may include a light-emitting unit including The surface emitting laser device according to the above-described embodiment, and a light-receiving unit for converting light energy such as a photodiode into electrical energy.

Features, structures, effects, and the like described in the above embodiments are included in at least one embodiment, and are not necessarily limited to only one embodiment. Furthermore, the features, structures, effects, and the like illustrated in each embodiment may be combined or modified for other embodiments by a person having ordinary skill in the field to which the embodiments belong. Therefore, contents related to such combinations and modifications should be interpreted as being included in the scope of the embodiments.

Although the embodiments have been described above, these are only examples and are not intended to limit the embodiments, and those of ordinary skill in the field to which the embodiments belong are not departing from the essential characteristics of the embodiments. It will be seen that branch transformation and application are possible. For example, each component specifically shown in the embodiment can be modified and implemented. And differences related to these modifications and applications should be construed as being included in the scope of the embodiments set in the appended claims.

### INDUSTRIAL APPLICABILITY

The surface emitting laser device according to the embodiment may be used for optical communication, optical parallel processing, optical connection, and the like.

For example, the surface emitting laser device according to the embodiment may be employed in a 3D sensing camera, and the 3D sensing camera may be implemented in two ways, such as a structured light (SL) method and a ToF (Time of Flight) method.

1. A surface emitting laser device, comprising:
a first reflective layer;
an active region disposed on the first reflective layer;
an aperture region disposed on the active region; and
a second reflective layer disposed on the aperture region,
wherein the second reflective layer includes a first AlGaAs-based layer including Alₓ₁Ga₍₁₋ₓ₁₎As; a second AlGaAs-based layer disposed on the first AlGaAs-based layer and including Alx₂Ga₍₁₋ₓ₂₎As; and an AlGaAs-based transition region disposed between the first AlGaAs-based layer and the second AlGaAs-based layer,
wherein the AlGaAs-based transition region includes a third AlGaAs-based layer containing Alₓ₃Ga₍₁₋ₓ₃₎As; and a fourth AlGaAs-based layer containing Alₓ₄Ga₍₁₋ₓ₄₎As,
wherein a plurality of layers in the third AlGaAs-based layer and the fourth AlGaAs-based layer are alternately arranged,
wherein the plurality of third AlGaAs-based layer become thinner in a direction from the first AlGaAs-based layer to the second AlGaAs-based layer, and
wherein the plurality of fourth AlGaAs-based layers become thinner in a direction from the second AlGaAs-based layer to the first AlGaAs-based layer.

2. The surface emitting laser device according to claim 1, wherein the Al concentration (X1) in the first AlGaAs-based layer and the Al concentration (X3) in the third AlGaAs-based layer are 8% to 20%, and the Al concentration (X2) in the second AlGaAs-based layer and Al concentration (X4) in the fourth AlGaAs-based layer are 80% to 92%.

3. The surface emitting laser device according to claim 2, wherein the Al concentration (X3) in the third AlGaAs-based layer is 12% to 20% or less.

4. The surface emitting laser device according to claim 2, wherein the Al concentration (X4) in the fourth AlGaAs-based layer is 80% to 88% or less.

5. The surface emitting laser device according to claim 1, wherein a thickness of the AlGaAs-based transition region is thinner than each of the first AlGaAs-based layer and the second AlGaAs-based layer.

6. The surface emitting laser device according to claim 5, wherein the thickness of the plurality of third AlGaAs-based layers gradually decreases in a direction from the first AlGaAs-based layer to the second AlGaAs-based layer, and a maximum thickness of one of the plurality of third AlGaAs-based layers is less than 4 nm.

7. A surface emitting laser device, comprising:
a first reflective layer;
an active region including an active layer on the first reflective layer:
an aperture region disposed on the active region and including an aperture and an insulating region; and
a second reflective layer on the aperture region,
wherein the second reflective layer includes a second-first reflective layer, a second-second reflective layer, and a second-third reflective layer disposed between the second-first reflective layer and the second-second reflective layer,
wherein a bandgap energy level of the second-third reflective layer is lower than a bandgap energy level of the second-second reflective layer, and is higher than the bandgap energy level of the second-first reflective layer, and
wherein the second reflective layer comprises a first superlattice tunneling layer between the second-second reflective layer and the second-third reflective layer.

8. The surface emitting laser device according to claim 7, wherein the first superlattice tunneling layer includes a first-first tunneling layer having a first energy level and a first-second tunneling layer having a second energy level lower than the first energy level, and
wherein the first energy level of the first-first tunneling layer is higher than the energy level of the second-second reflective layer, and
wherein the second energy level of the first-second tunneling layer is lower than the energy level of the second-second reflective layer.

9. A surface emitting laser device, comprising:
a first reflective layer;
an active region including an active layer on the first reflective layer;
an aperture region disposed on the active region and including an aperture and an insulating region; and
a second reflective layer on the aperture region,
wherein the second reflective layer comprises a second-first reflective layer, a second-second reflective layer, and a second-third reflective layer between the second-first reflective layer and the second-second reflective layer,
wherein the bandgap energy level of the second-third reflective layer is lower than the bandgap energy level of the second-second reflective layer, is higher than the bandgap energy level of the second-first reflective layer,
wherein the second reflective layer includes a grading reflective layer between the second-first reflective layer and the second-third reflective layer or between the second-second reflective layer and the second-third reflective layer, and
wherein the band gap energy level of the grading reflective layer comprises a rounding area.

10. A light emitting device comprising the surface emitting laser device according to claim 1.

11. The surface emitting laser device according to claim 6, wherein a thickness of the plurality of fourth AlGaAs-based layers gradually decreases from the second AlGaAs-based layer toward the first AlGaAs-based layer.

12. The surface emitting laser device according to claim 11, wherein a maximum thickness of one of the plurality of fourth AlGaAs-based layers is less than 4 nm.

13. The surface emitting laser device according to claim 7, wherein the second reflective layer includes a second superlattice tunneling layer between the second-third reflective layer and the second-second reflective layer.

14. The surface emitting laser device according to claim 13, wherein the second superlattice tunneling layer comprises a first-third tunneling layer of a third energy level and a first-fourth tunneling layer of a fourth energy level lower than the third energy level

15. The surface emitting laser device according to claim 14, wherein the third energy level of the first-third tunneling layer is higher than the energy level of the second-second reflective layer, and the fourth energy level of the first-fourth tunneling layer is lower than the energy level of the second-second reflective layer.

16. The surface emitting laser device according to claim 9, wherein the second reflective layer includes a first grading reflective layer between the second-third reflective layer and the second-second reflective layer,
wherein the second-third reflective layer comprises a composition of Alₓ₃Ga₍₁₋ₓ₃₎As(0.12≤X3≤0.88), and
wherein the first graded reflective layer 251g1 comprises a composition of Al_{g1}Ga_{(1-g1)}As(0.12≤g1≤X3).

17. The surface emitting laser device according to claim 16, wherein the first Al composition of the first graded reflective layer decreases along a curved slope from the second-third reflective layer to the second-second reflective layer.

18. The surface emitting laser device according to claim 17, wherein the second reflective layer includes a third grading reflective layer between the second-third reflective layer and the second-first reflective layer, and
wherein the third graded reflective layer includes a composition of Al_{g3}Ga_{(1-g3)}As(X3≤g3≤0.88), and
wherein the third Al composition of the third graded reflective layer increases along a curved slope from the second-third reflective layer to the second-first reflective layer.

19. A light emitting device comprising the surface emitting laser device according to claim 7.

20. A light emitting device comprising the surface emitting laser device according to claim 9.
